(19) United States
(12) Patent Application Publication
(10) Pub. No.: US 2006/0001055 A1
(43) Pub. Date: Jan. 5, 2006

(54) Led and fabrication method of same

(76) Inventors: Kazuhiko Ueno, Tokyo (JP); Yoshiaki Yasuda, Tokyo (JP); Masanao Tani, Tokyo (JP)

Correspondence Address: CERMAK & KENEALY, LLP, 515 EAST BRADDOCK RD SUITE B, Alexandria, VA, 22314, US

(21) Appl. No.: 11/062,772

(22) Filed: Feb. 22, 2005

(30) Foreign Application Priority Data
Nov. 24, 2004 (JP) 2004-338624
Feb. 23, 2004 (JP) 2004-46173

(51) Int. Cl. H01L 29/80

(52) U.S. Cl. 257/257

(57) ABSTRACT

An LED can include a silicon substrate and a pair of electrodes formed inside a horn that is formed on the silicon substrate by anisotropic etching. The LED can include an LED chip mounted inside the horn, the LED chip being electrically connected to the pair of electrodes. A resin mold made of a resin material can be filled in the horn.

This application claims the priority benefit under 35 U.S.C. §119 of Japanese Patent Application No. 2004-338624 filed on Nov. 24, 2004 and Japanese Patent Application No. 2004-046173 filed on Feb. 23, 2004, which are both hereby incorporated in their entirety by reference.

### BACKGROUND OF THE INVENTION

1. Field of the Invention

The present invention relates to an LED and a fabrication method of the LED.

2. Description of the Related Art

Conventionally, an LED such as a power white LED is configured as shown in FIG. 34. Namely, as shown in FIG. 34, an LED 1 is configured by forming a horn 2a, which results from a concave recessed portion, on a conductive substrate 2 including a metal such as copper that has a high thermal conductivity, directly mounting an LED chip 3 on the bottom surface of the horn 2a, thereafter disposing phosphors (not shown) inside the horn 2a, and covering the periphery and surface of the conductive substrate 2 with an insulator 4 such as a resin or ceramic.

According to the LED 1 of this configuration, the LED chip 3 is supplied with electricity from the outside, whereby the LED chip 3 is driven and emits light, the light emitted from the LED chip 3 is directly reflected or reflected by the inner walls of the horn 2a, thereafter strikes the phosphors, excites the phosphors, and the light becomes white due to the mixing of the colors of the excitation light and the light from the LED chip 3 and is emitted to the outside.

As shown in FIG. 35, an LED 1′ of a configuration where a sub-mount substrate 5, which comprises a ceramic or silicon in which an electrode is formed by patterning, is disposed on the bottom surface of the horn 2a and the LED chip 3 is mounted on the sub-mount substrate 5 is also known.

An LED 6 of a configuration as shown in FIG. 36 is also known. As shown in FIG. 36, the LED 6 is configured by forming a horn 7a, which results from a concave recessed portion, on an insulator substrate 7 such as a ceramic or resin, patterning an electrode 7b by printing, plating or depositing the electrode inside the horn 7a, thereafter mounting the LED chip 3 on the electrode 7b, and then disposing phosphors (not shown) inside the horn 7a.

It should be noted that, as shown in FIG. 37, the horn 7a may also be configured by laminating a thin insulator substrate. According to the LED 6 of this configuration, the LED chip 3 is similarly supplied with electricity from the outside, whereby the LED chip 3 is driven and emits light, the light emitted from the LED chip 3 is directly reflected or reflected by the inner walls of the horn 7a, thereafter strikes the phosphors, excites the phosphors, and the light becomes white due to the mixing of the colors of the excitation light and the light from the LED chip 3 and is emitted to the outside.

An LED 8 of a configuration as shown in FIG. 38 is also known. As shown in FIG. 38, the LED 8 has substantially the same configuration as that of the LED 6 shown in FIG. 36, and has the different configuration of a plural of LED chips 3 (two LED chips in the drawings) mounted in the horn 7a.

With respect to the LED 1, it may be necessary to mutually connect the LED chips 3 in parallel when fabricating a multichip LED, because a metal with a high thermal conductivity is used for the mount portions of the LED chips 3, and the current is supplied to the LED chips via the mount portion. For this reason, the current ends up being concentrated at the LED chips 3, whose Vf resulting from variation is low, and sometimes the lifespan ends up becoming short.

In contrast, with respect to the LED 1′, it is possible to mutually connect the LED chips 3 in series when fabricating a multichip LED because the sub-mount substrate 5 is used, but the number of parts increases, the cost of the parts and assembly costs become high, and the number of joint portions increases. Thus, there is the problem that thermal resistance at the time of operation ends up increasing.

Also, with respect to the LED 6, it is possible to mutually connect the LED chips 3 in series when fabricating a multichip LED because the electrode is patterned with respect to the insulator substrate 7, but the light emission efficiency drops, the emitted light beams are reduced, and the lifespan drops because the insulator configuring the insulator substrate 7 has a low thermal conductivity.

With respect thereto, ceramic materials such as an AlN ceramic have come to be developed as insulators with a high thermal conductivity, but there are the problems that the cost of the materials themselves is high and the processability is poor.

Moreover, with respect to the LED 1, the LED 1′ and the LED 6, there is a limit on the extent to which the chips can be made compact because it is necessary to form the horns 2a and 7a in both, and incorporating other elements and circuits inside the package has been substantially difficult.

Furthermore, with respect of the LED 8, the total power of light, namely the power of light taken out upward falls down less than the sum of the individual powers of each LED chip 3, because the light absorption among the LED 6 depends on the distance of the LED chips 3, and because the light that emitted from each LED chips 3 is reflected by the inclined side surface of the horn 7a and returned to the LED chips 3 is absorbed by the LED chips 3.

With respect of the brightness distribution of the light taken out upward, the variation is produced accordance with the distances among each LED chip 3 and the above mentioned light absorption of the LED chips 3.

With respect thereto, by providing a partition made of the non-transparent material, the light absorption among each LED chip 3 can be excluded. But, in the case the partition is provided by machine-working or resin molding, the distance between each LED chip 3 is widened, so that the characteristic of the light distribution become worse and the uneven brightness occurs.

Moreover, with respect to the LED 1, the LED 1′, the LED 6 and the LED 8, as shown in the FIG. 39, for example in the case that the LED 6 is mounted on the mounting board 9 such as the printed board, the flexible board etc. (or lead frame), for electrically connecting the LED chip to the connecting portion 9a of the conductive pattern on the mounting board 9, the bonding wire 9b (or lead wire) is necessary, because the so-called reflow-soldering for improving the efficiency of the mounting process cannot be carried out.

Accordingly, since a joining strength or an insulation of the above mentioned bonding wire or lead wire are insufficient, it is necessary to cover these by a resin molding or a package for protecting these bonding wire or lead wire. So, the advantages of a small- or thin-size of the LED package cannot be utilized.

With respect of fixing the LED 1 on the mounting board 9, an adhesive is needed, and in the case that the LED is mounted adjacent to other parts such as a lens-module etc., the above mentioned bonding wire can be interfered, and it is difficult to the LED on the mounting board with maintaining the heat-radiation.

### SUMMARY OF THE INVENTION

In light of the above, in accordance with an aspect of the invention, an LED and a fabrication method thereof can be provided where a rise in temperature resulting from heat emission can be excellently suppressed, where the fabrication of a multichip LED is easily possible, and which can be easily and compactly configured, where, in the case of a plural of LED chips are provided, a light power is raised as high as possible, and where the LED can be mounted easily without a bonding wire.

The conventional art has several drawbacks. In accordance with an aspect of the invention, the following exemplary advantages and features can be provided;

(1) in the working process of the silicon substrate, a dry process is not needed,

(2) in the process of electrode patterning, a contact is formed by a spray method or an electro-forming method, not by a laser trimming process,

(3) an electrode pattern can be formed only on a LED-mounted surface of the silicon substrate, and is not necessarily formed on a back surface of the silicon substrate,

(4) it is possible to provide a dummy pattern for heat-radiation on a back surface of the silicon substrate.

In accordance with another aspect of the invention there can be provided an LED including a silicon substrate; a pair of electrodes can be formed inside a horn formed on the silicon substrate by anisotropic etching; an LED chip can be mounted inside the horn, the LED chip being electrically connected to the pair of electrodes; and a resin mold can be made of a resin material that is filled in the horn.

The horn can be formed by etching the silicon substrate from an upper surface of the silicon substrate to an intermediate height and that each electrode be formed so as to extend along the surface of the silicon substrate from a bottom surface of the horn via side surfaces of the horn. The silicon substrate may include a flat first substrate having a surface on which the electrodes are formed and a second substrate laminated on the first substrate, the second substrate being provided with the horn that vertically penetrates the second substrate. The LED chip can be die-bonded to one of the pair of electrodes inside the horn and is wire-bonded to the other of the pair of electrodes inside the horn. The LED chip can be mounted so as to straddle the pair of electrodes inside the horn, with electrodes formed at both lower side edges of the LED chip being electrically connected respectively to the pair of electrodes inside the horn. The silicon substrate may be formed with a (100) surface serving as the surface, and the side surfaces of the horn may be formed as (111) surfaces. The side surfaces of the horn can be provided with a mirror surface on the surfaces. An actuator and an IC circuit may be formed adjacent to the horn on the silicon substrate. Granular phosphors may be mixed in with the resin material forming the resin mold.

In accordance with another aspect of the invention there can be provided a method of fabricating an LED that can include providing a silicon substrate having a surface in which a horn is formed by anisotropic etching, the horn having a pair of electrodes formed therein; mounting an LED chip inside the horn such that the LED chip is electrically connected to the pair of electrodes; and filling the interior of the horn with a resin material to form a resin mold.

The LED chip can be supplied with electricity from the outside via the electrodes, whereby the LED chip is driven. Then, the light emitted from the LED chip can be directly reflected or reflected by the bottom surface or the side surfaces of the horn of the silicon substrate and emitted upward via the resin mold.

In this case, the substrate on which the LED chip is mounted is configured by a silicon substrate with a high thermal conductivity (about 150 W/m·k), and it becomes possible to thin the thickness of the substrate. Thus, as will be understood from the following equation, thermal resistance is reduced and the heat generated by the LED at the time the LED is driven is efficiently dissipated via the substrate.
Thermal Resistance=Thickness of Substrate (m)/
Thermal Conductivity (W/m·K)×Electrothermal Cross-Sectional Area (m²)

Thus, a rise in the temperature of the LED chip is suppressed, and there is no drop in the light emission efficiency of the LED chip due to heat. Thus, the emitted light beams are not reduced by the generated heat of the LED chip and the lifespan does not drop.

Additionally, because the electrodes for electrical connection to the LED chip are formed by patterning, it is possible to mutually connect the LED chips in series when fabricating a multichip LED.

Moreover, the horn 11a is microfabricated on the silicon substrate by a semiconductor fabrication technique, it is possible to integrally configure, with the LED chip, other semiconductor devices such as an IC. Thus, it becomes possible to incorporate an LED chip drive circuit and the LED can be compactly configured including the drive circuit.

In a case where the horn is formed by etching the silicon substrate from the upper surface of the silicon substrate to an intermediate height and each electrode is formed so as to extend along the surface of the silicon substrate from a bottom surface of the horn via side surfaces of the horn, the silicon substrate disposed with the horn can be configured in an integrated structure and can be fabricated by an easy process.

In this case, because the thickness of the silicon substrate inside the horn can be controlled by time management when the horn is etched, the thermal resistance of the silicon substrate with respect to the LED chip can be reduced.

It should be noted that the specific thickness of the substrate in this case can be 0.1 to 0.5 mm in view of the rigid balance with thermal resistance.

In a case where the silicon substrate is configured from a flat first substrate including a surface on which the electrodes are formed and a second substrate laminated on the first substrate, and the second substrate is disposed with the horn that vertically penetrates the second substrate, electrodes and a wiring pattern of complex shapes can be formed on the first substrate, whereby it is possible to easily incorporate a drive circuit for the LED chip.

In a case where the LED chip is die-bonded to one electrode inside the horn and wire-bonded to the other electrode, an LED chip disposed with electrodes at the top and bottom can be easily mounted inside the horn.

In a case where the LED chip is mounted so as to straddle the electrodes inside the horn and electrodes formed at both lower side edges of the LED chip are electrically connected to both of the electrodes inside the horn, a so-called flip chip type LED chip disposed with electrode portions at both side edges of the lower surface can be easily mounted inside the horn.

In a case where the silicon substrate is formed with a (100) surface serving as the surface and the side surfaces of the horn are formed as (111) surfaces, side surfaces with a predetermined inclination angle can be easily formed by anisotropic etching. In this case, the (111) surfaces are processed to 54.7°.

In a case where the side surfaces of the horn are disposed with a mirror surface on the surface, the light emitted from the LED chip is reflected by the mirror surface disposed at the surface when the light is made incident at the side surfaces of the horn, whereby the reflectivity at the side surfaces of the horn becomes higher and reflection efficiency is improved. Thus, the emission efficiency of the light from the LED is improved. In this case, as the mirror material, Au and Al can be used for a red LED and Ag and Al can be used for a blue LED.

In a case where an actuator and an IC circuit are formed adjacent to the horn on the silicon substrate, the optical axis of the light emitted from the LED is swung by the actuation of the actuator or part of the light-emitting portion is blocked off, whereby the light distribution characteristics and the shape of the light-emitting portion can be changed. Thus, for example, when the LED is used as the light source of an automobile headlight, it becomes possible to switch the high beam and the low beam and to realize a so-called AFS function.

In a case where granular phosphors are mixed in with the resin material forming the resin mold, the light emitted from the LED chip strikes these phosphors and excites the phosphors, whereby the color of the excitation light from the phosphors and the color of the light from the LED chip become mixed, and the mixed color light is emitted to the outside. Thus, white light can be obtained.

According to the second configuration, in the completed LED, the LED chip is supplied with electricity from the outside via the electrodes, whereby the LED chip is driven. Then, the light emitted from the LED chip is directly reflected or reflected by the bottom surface or the side surfaces of the horn of the silicon substrate and is emitted upward via the resin mold.

Additionally, because the substrate on which the LED chip is mounted is configured by a silicon substrate with a high thermal conductivity, the heat generated by the LED chip at the time the LED chip is driven is efficiently dissipated via the substrate. Thus, a rise in the temperature of the LED chip is suppressed, and there is no drop in the emission efficiency of the LED chip due to heat. Thus, the emitted light beams are not reduced by the generated heat of the LED chip and the lifespan does not drop.

In this case, because the silicon substrate disposed with the horn can be easily fabricated using an existing semiconductor fabrication device, the LED can be fabricated relatively easily and at a relatively low cost.

In accordance with another aspect of the invention, an LED can include a silicon substrate; a horn formed on the silicon substrate by liquid phase etching; at least two electrodes formed inside the horn; at least one LED chip mounted inside the horn, the LED chip being electrically connected to the electrodes; and a resin mold made of a resin material that is filled in the horn.

The electrodes can be drawn out from the horn, and electrically contact with lead frames. The horn can be formed by etching the silicon substrate from an upper surface of the silicon substrate to a height above a lower surface so as not to pass through completely the substrate and that each electrode is formed so as to extend along the surface of the silicon substrate from a bottom surface of the horn via side surfaces of the horn. The silicon substrate may include a flat first substrate having a surface on which the electrodes are formed and a second substrate laminated on the first substrate, the second substrate being provided with the horn that vertically penetrates the second substrate. Each LED chip can be die-bonded to one of the electrodes inside the horn and is wire-bonded to another electrode inside the horn. Each LED chip can be mounted so as to straddle two of electrodes inside the horn, with electrodes formed at both lower side edges of the LED chip being electrically connected respectively to the two electrodes inside the horn. The side surfaces of the horn may be formed as any of (111), (110) or (100) surfaces. The side surfaces of the horn can be provided with a mirror surface on the surfaces. An actuator may be formed on the silicon substrate. An electronic circuit may be formed on the silicon substrate. The electronic circuit can be any of a photo-diode, a transistor, an IC, or the like.

A resin can be filled in the horn. Phosphors may be mixed in with the resin. The horn may have a partition wall that surrounds respectively each LED chip. The upper end of the partition wall may be flat in height as same as a height of an upper surface of the silicon substrate. The upper end of the partition wall may have a crest line in height as same an upper surface of the silicon substrate. The upper end of the partition wall may have a crest line in height lower than an upper surface of the silicon substrate. The side surface of the partition wall may have a flat, convex or concave form. The side surfaces of the partition wall may be formed as any of(111), (110) or (100) surfaces.

In accordance with another aspect of the invention, an LED can include a silicon substrate; a horn formed on the silicon substrate by liquid phase etching; at least two contact-holes formed on the silicon substrate by liquid phase etching; at least two electrodes extended respectively from inside of the horn to the lower end of each contact-hole; and at least one LED chip mounted inside the horn, the LED chip being electrically connected to the electrodes.

In accordance with another aspect of the invention, an LED can include a silicon substrate; a horn formed on the silicon substrate by liquid phase etching; at least two contact-edges formed on the silicon substrate by liquid phase etching; at least two electrodes extended respectively from inside of the horn to the lower end of each contact-edge; and at least one LED chip mounted inside the horn, the LED chip being electrically connected to the electrodes.

The silicon substrate has a rectangular form in a view from LED-chip-mounted side, and the contact-edges is formed at least on one of the four corner of the rectangular form. A metal thin film is provided on the lower surface of the silicon substrate at least in the region of the horn. The silicon substrate may be arranged via the metal thin film to the heat-radiating member. A lens may be arranged on the horn. The lens may be a convex lens. The lens may be a spherical lens. A recess for positioning the lens may be formed around the horn on the silicon substrate.

In accordance with another aspect of the invention, a method of fabricating an LED can include a process of forming a horn on a silicon substrate by liquid phase etching; a process of forming at least two electrodes inside the horn; a process of mounting at least one LED chip inside the horn such that the LED chip is electrically connected to the electrodes.

The method can include a process of filling the interior of the horn with a resin material to form a resin mold. In the process of forming a horn on the silicon substrate by liquid phase etching, a plural of horns may be formed adjacent each other, and a partition wall may be formed between the horns. The upper end of the partition wall may be in height as same as, or lower than, a height of an upper surface of the silicon substrate. The surface of the partition wall may have a convex or concave form.

In accordance with another aspect of the invention, a method of fabricating an LED can include a process of forming an oxidized film on a surface of a silicon substrate; a process of patterning the oxidized film so as to expose each portion to be a contact-hole; a process of forming a shallow recess in each portion to be a contact-hole by liquid phase etching; a process of patterning the oxidized film so as to expose each portion to be a horn; a process of forming horns and contact-holes on the silicon substrate by liquid phase etching; a process of an insulating film on the surface of the silicon substrate; a process of forming electrode-patterns on the silicon substrate; a process of mounting at least one LED chip inside each horn such that the LED chip is electrically connected to the electrodes; and a process of cutting out the silicon substrate.

In accordance with another aspect of the invention, a method of fabricating an LED can include a process of forming an oxidized film on a silicon substrate; a process of patterning the oxidized film so as to expose each portion to be a through-bore; a process of forming a shallow recess in each portion to be a through-bore by liquid phase etching; a process of patterning the oxidized film so as to expose each portion to be a horn; a process of forming horns and through-bores on the silicon substrate by liquid phase etching; a process of an insulating film on the surface of the silicon substrate; a process of forming electrode-patterns on the silicon substrate; a process of mounting at least one LED chip inside each horn such that the LED chip is electrically connected to the electrodes; and a process of cutting out the silicon substrate so as to cross each through-bore to form a contact edge.

In accordance with another aspect of the invention, a method of fabricating an LED can include a process of forming at least two electrodes on a first silicon substrate; a process of forming through-bores on a second silicon substrate by liquid phase etching and forming a horn on the side wall of each through-bore; a process of bonding the first and second silicon substrates each other so as to expose the electrodes in each through-bore; and a process of mounting at least one LED chip inside the horn such that the LED chip is electrically connected to the electrodes.

The method can include a process of forming a mirror surface in an inner surface of each through-bore; and/or a process of filling the interior of the horn with a resin material to form a resin mold; and/or a process of insulating the surfaces of silicon substrates by oxidized film.

According to the third configuration, each of the LED chips is supplied with electricity from the outside via the electrodes, whereby each LED chip is driven. Then, the light emitted from each LED chip is directly reflected or reflected by the bottom surface or the side surfaces of the horn of the silicon substrate and is emitted upward via the resin mold.

In this case, the substrate on which the LED chips are mounted is configured by a silicon substrate with a high thermal conductivity (about 150 W/m·k), and it becomes possible to thin the thickness of the substrate. Thus, as will be understood from the following equation, thermal resistance is reduced and the heat generated by each LED at the time each LED is driven is efficiently dissipated via the substrate.
Thermal Resistance=Thickness of Substrate (m)/Thermal Conductivity (W/m·K)×Electrothermal Cross-Sectional Area (m²)

Thus, a rise in the temperature of each LED chip is suppressed, and there is no drop in the light emission efficiency of each LED chip due to heat. Thus, the emitted light beams are not reduced by the generated heat of each LED chip and the lifespan does not drop. Additionally, because the electrodes for electrical connection to each LED chip are formed by patterning, it is possible to mutually connect the LED chips in series when fabricating a multichip LED.

Moreover, the horn 11a is microfabricated on the silicon substrate by a semiconductor fabrication technique, it is possible to integrally configure, with the LED chips, other semiconductor devices such as an IC. Thus, it becomes possible to incorporate an LED chip drive circuit and the LED can be compactly configured including the drive circuit.

In a case where the horn is formed by etching the silicon substrate from the upper surface of the silicon substrate to a height above a lower surface so as not to pass through completely the substrate and where each electrode is formed so as to extend along the surface of the silicon substrate from a bottom surface of the horn via side surfaces of the horn, the silicon substrate disposed with the horn can be configured in an integrated structure and can be fabricated by an easy process.

In this case, because the thickness of the silicon substrate inside the horn can be controlled by time management when the horn is etched, the thermal resistance of the silicon substrate with respect to each LED chip can be reduced.

It should be noted that the specific thickness of the substrate in this case can be 0.1 to 0.5 mm in view of the rigid balance with thermal resistance.

In a case where the silicon substrate is configured from a flat first substrate including a surface on which the electrodes are formed and a second substrate laminated on the first substrate, and the second substrate is disposed with the horn that vertically penetrates the second substrate, electrodes and a wiring pattern of complex shapes can be formed on the first substrate, whereby it is possible to easily incorporate a drive circuit for the LED chips.

In a case where the LED chips are die-bonded to one electrode inside the horn and wire-bonded to another electrode, an LED chip disposed with electrodes at the top and bottom can be easily mounted inside the horn.

In a case where each of the LED chips is mounted so as to straddle the electrodes inside the horn and electrodes formed at both lower side edges of each LED chip are electrically connected to both of the electrodes inside the horn, a so-called flip chip type LED chip disposed with electrode portions at both side edges of the lower surface can be easily mounted inside the horn.

In a case where the silicon substrate is formed with a (100) surface serving as the surface and the side surfaces of the horn are formed as (111) surfaces, side surfaces with a predetermined inclination angle can be easily formed by anisotropic etching. In this case, the (111) surfaces are processed to 54.7°.

Although in the above description the silicon substrate with a (100) surface and the horn with a (111) side surface are adopted, but a silicon substrate with a (110) surface or an off-axised substrate can be used, and an inclined angle of the horn must not be 54.7°. For example, in the case that a horn is formed on a substrate with a (110) surface, by etching with enchant of TMAH and a mask-pattern, a straight part of which is parallel to a orientation-flat corresponding to (100) surface, an side surface of the formed horn is vertical. Here, the horn with the vertical side surface is useful to construct a light source which positively reduces a light emitting area and raises a brightness, for example, a head-lamp for vehicle etc.

With respect of the substrate with a (100) surface, in the case that a horn is formed on a substrate with a (110) surface, by etching with etchant of EDP and a mask-pattern, a straight part of which is 45° to a orientation-flat corresponding to (100) surface, an inclined angle of the formed horn is 45°. And under the same condition, by etching with etchant of KOH, an inclined angle of the formed horn is 90° (vertical). Therefore, in the above embodiment, a substrate with a (100) surface is described, but by changing suitably a crystal orientation of a substrate, a form of a mask-pattern and an etchant depending on a purpose of use, any device with a required horn-form can be produces.

In a case where the side surfaces of the horn are disposed with a mirror surface on the surface, the light emitted from each LED chip is reflected by the mirror surface disposed at the surface when the light is made incident at the side surfaces of the horn, whereby the reflectivity at the side surfaces of the horn becomes higher and reflection efficiency is improved. Thus, the emission efficiency of the light from the LED is improved. In this case, as the mirror material, Au and Al can be used for a red LED and Ag, Al and an alloy of those can be used for a blue LED.

In a case where an actuator are formed adjacent to the horn on the silicon substrate, the optical axis of the light emitted from the LED is swung by the actuation of the actuator or part of the light-emitting portion is blocked off, whereby the light distribution characteristics and the shape of the light-emitting portion can be changed. Thus, for example, when the LED is used as the light source of an automobile headlight, it becomes possible to switch the high beam and the low beam and to realize a so-called AFS function.

In a case where granular phosphors are mixed in with the resin material forming the resin mold, the light emitted from each LED chip strikes these phosphors and excites the phosphors, whereby the color of the excitation light from the phosphors and the color of the light from each LED chip become mixed, and the mixed color light is emitted to the outside. Thus, white light can be obtained.

In a case where the horn has a partition wall that surrounds respectively each LED chip, the light emitted from each LED chip and oriented to the adjacent LED chip is intercepted by the partition wall, so that an absorption of light among the LED chips is prevented. Thus, the lost of light is reduced and the total power of light taken out upward is raised.

In a case where the upper end of the partition wall is flat in height as same as a height of a upper surface of the silicon substrate, or in a case where the upper end of the partition wall has a crest line in height as same a upper surface of the silicon substrate, the light emitted from each LED chip is reflected by the side surfaces of the corresponding horn and the partition wall, and led to upward, so that the total power of light taken out upward is raised, and each distance between the LED chips can be suitably adjusted.

In a case where the upper end of the partition wall has a crest line in height lower than a upper surface of the silicon substrate, each distance between the LED chips can be optimally adjusted even if the distance between the LED chips is too long by the upper end of the partition wall being in height as same as a height of a upper surface of the silicon substrate.

In a case where the side surface of the partition wall has a flat, convex or concave form, with respect to the light emitted from each LED chip and oriented the side surface of the partition wall, the optimal reflecting characteristic in the reflecting by the side surface can be obtained by selecting the form of the side surface of the partition wall.

In a case where the side surfaces of the partition wall may be formed as a (111) surfaces, the side surface with inclined angle 54.7° of the partition wall is obtained at the same time of the horn forming by liquid phase anisotropic etching.

In a case where the silicon substrate has at least two contact-holes which pass through the silicon substrate vertically adjacent the horn, each electrodes extending respectively from inside of the horn to the lower end of each corresponding contact-hole via the contact-hole, for the LED is mounted on a mounting-board, the electrodes can be connected directly to a corresponding contact portion on the mounting-board, without using bonding-wire or lead wire, by, for example, reflow-soldering or eutectic junction.

In this case, the contact-holes can be formed at the same time of forming a horn on the substrate, so that these can be processed easily and in large quantities by a semiconductor fabrication processes.

In a case where the silicon substrate has at least two contact-edges which pass through the silicon substrate vertically at the side surfaces, each electrodes extending respectively from inside of the horn to the lower end of each corresponding contact-edge via the contact-edge, as same as the contact-holes, for the LED is mounted on a mounting-board, the electrodes can be connected directly to a corresponding contact portion on the mounting-board, without using bonding-wire or lead wire, by, for example, reflow-soldering or eutectic junction.

In this case, the contact-edges can be formed by that contact-holes are formed at the same time of forming a horn on the substrate, and each of the contact-holes are cut off at the same time of dicing the substrate, so that these can be processed easily and in large quantities by a semiconductor fabrication processes.

In a case where the silicon substrate is provided with a metal thin film at least in an area of the horn on lower surface, for the LED is mounted on a mounting-board, the LED can be fixed rigidly to a mounting-board by the metal thin film, so that a heat radiation from the LED to a mounting-board is improved better.

According to the fourth configuration, in the completed LED, each of the LED chips is supplied with electricity from the outside via the electrodes, whereby each LED chip is driven. Then, the light emitted from each LED chip is directly reflected or reflected by the bottom surface or the side surfaces of the horn of the silicon substrate and is emitted upward via the resin mold.

Additionally, because the substrate on which each LED chip is mounted is configured by a silicon substrate with a high thermal conductivity, the heat generated by each LED chip at the time each LED chip is driven is efficiently dissipated via the substrate. Thus, a rise in the temperature of each LED chip is suppressed, and there is no drop in the emission efficiency of each LED chip due to heat. Thus, the emitted light beams are not reduced by the generated heat of each LED chip and the lifespan does not drop.

In this case, because the silicon substrate disposed with the horn can be easily fabricated using an existing semiconductor fabrication device, the LED can be fabricated relatively easily and at a relatively low cost.

In this manner, an LED and a fabrication method thereof are provided, where a rise in temperature resulting from heat emission can be excellently suppressed, where the fabrication of a multichip LED is easily possible, and which can be easily and compactly configured, and furthermore where a power of light is raised as high as possible in case of providing with a plural of LED chips, and which can be easily mounted on a mounting-board without using a bonding-wire.

### BRIEF DESCRIPTION OF THE DRAWINGS

The above and other aspects, features and advantages of the invention will become more apparent from the following detailed description when taken in conjunction with the accompanying drawings, in which:

FIG. 1 is a schematic cross-sectional view showing a first embodiment of an LED made in accordance with the principles of the invention;

FIG. 2 is a schematic cross-sectional view showing a second embodiment of an LED made in accordance with the principles of the invention;

FIG. 3 is a schematic cross-sectional view showing a third embodiment of an LED made in accordance with the principles of the invention;

FIG. 4 is a schematic plan diagram showing a fourth embodiment of an LED made in accordance with the principles of the invention;

FIG. 5 is a schematic plan diagram showing a state at the time of operation of a thermoelectric actuator in the LED of FIG. 4;

FIG. 6 is a schematic perspective diagram showing the configuration of a fifth embodiment of an LED made in accordance with the principles of the invention;

FIG. 7 is a schematic cross-sectional view showing a sixth embodiment of an LED made in accordance with the principles of the invention;

FIG. 8 is a schematic cross-sectional view showing a seventh embodiment of an LED made in accordance with the principles of the invention;

FIG. 9 is a schematic cross-sectional view showing an eighth embodiment of an LED made in accordance with the principles of the invention;

FIG. 10 is a schematic plan diagram showing a ninth embodiment of an LED made in accordance with the principles of the invention;

FIG. 11 is a schematic plan diagram showing a state at the time of operation of a thermoelectric actuator in the LED of FIG. 10;

FIG. 12 is a schematic perspective diagram showing the configuration of a tenth embodiment of an LED made in accordance with the principles of the invention;

FIG. 13 is drawings showing the configuration of a eleventh embodiment of an LED made in accordance with the principles of the invention, respectively (A) in a schematic plan view and (B) in a schematic cross-sectional view;

FIG. 14 is drawings showing the configuration of a variant embodiment of an LED of FIG. 13, respectively (A) in a schematic plan view and (B) in a schematic cross-sectional view;

FIG. 15 is drawings showing the manufacturing processes of the LED of FIG. 13;

FIG. 16 is drawings showing the configuration of a twelfth embodiment of an LED made in accordance with the principles of the invention, respectively (A) in a schematic plan view and (B) in a schematic cross-sectional view;

FIG. 17 is drawings showing the manufacturing processes of the LED of FIG. 16;

FIG. 18 is a schematic cross-sectional view showing a variant of an LED of FIG. 16;

FIG. 19 is a schematic cross-sectional view showing another variant of an LED of FIG. 16;

FIG. 20 is drawings showing the configuration of a thirteenth embodiment of an LED made in accordance with the principles of the invention, respectively (A) in a schematic cross-sectional view and (B) in a schematic plan view;

FIG. 21 is drawings showing the manufacturing processes of the LED of FIG. 20;

FIG. 22 is drawings showing the configuration of a fourteenth embodiment of an LED made in accordance with the principles of the invention, respectively (A) in a schematic cross-sectional view and (B) in a schematic plan view;

FIG. 23 is drawings showing the manufacturing processes of the LED of FIG. 22;

FIG. 24 is a schematic cross-sectional view showing a fifteenth embodiment of an LED made in accordance with the principles of the invention in a mounting state;

FIG. 25 is drawings showing the configuration of a sixteenth embodiment of an LED made in accordance with the principles of the invention, respectively (A) in a schematic cross-sectional view and (B) in a schematic plan view;

FIG. 26 is a schematic cross-sectional diagram showing the LED of FIG. 25 mounted to a heat sink;

FIG. 27 is a schematic perspective view showing a seventeenth embodiment of an LED made in accordance with the principles of the invention in a mounting state;

FIG. 28 is a schematic cross-sectional view showing the seventeenth embodiment of an LED made in accordance with the principles of the invention in a mounting state;

FIG. 29 is drawings showing the configuration of an eighteenth embodiment of an LED made in accordance with the principles of the invention, respectively (A) in a schematic front view and (B) in a schematic plan view in a mounting state;

FIG. 30 is a schematic perspective view showing a nineteenth embodiment of an LED made in accordance with the principles of the invention in a mounting state;

FIG. 31 is a schematic perspective view showing a twentieth embodiment of an LED made in accordance with the principles of the invention in a mounting state;

FIG. 32 is a schematic perspective view showing a twenty-first embodiment of an LED made in accordance with the principles of the invention in a mounting state;

FIG. 33 is a schematic front view showing the twenty-first embodiment of an LED made in accordance with the principles of the invention in a mounting state;

FIG. 34 is a schematic cross-sectional view showing an example configuration of a conventional LED;

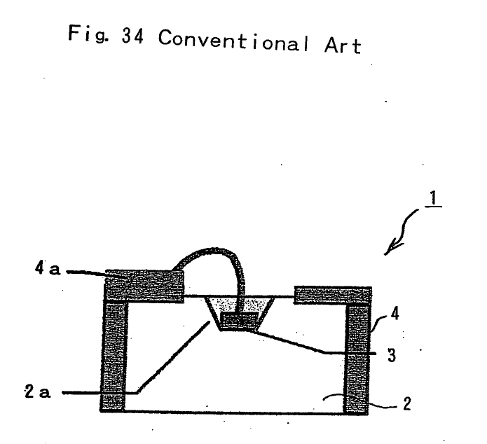

FIG. 35 is a schematic cross-sectional view showing another example configuration of a conventional LED;

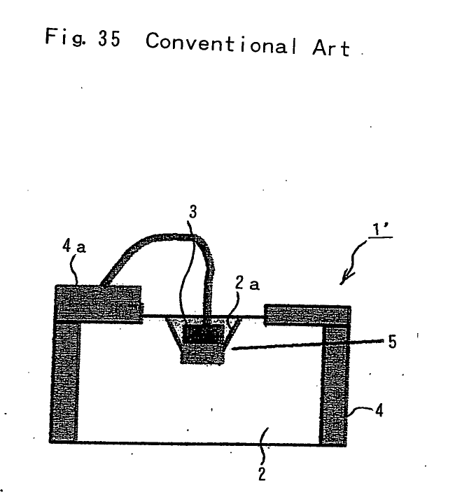

FIG. 36 is a schematic cross-sectional view showing yet another example configuration of a conventional LED; and

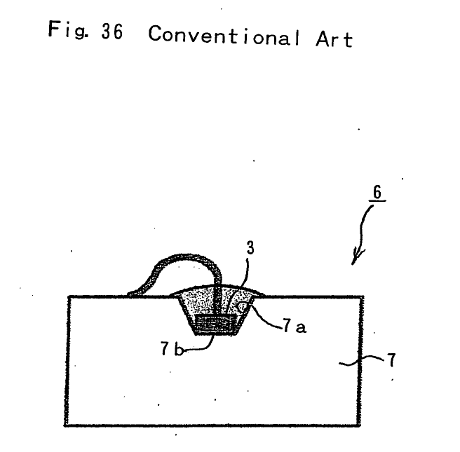

FIG. 37 is a schematic cross-sectional view showing a modified example of the conventional LED shown in FIG. 36.

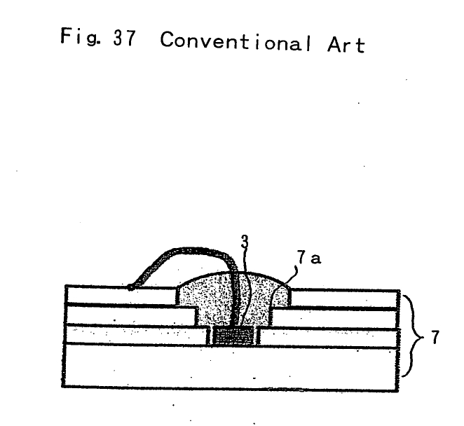

FIG. 38 is a schematic cross-sectional view showing yet another example configuration of a conventional LED; and

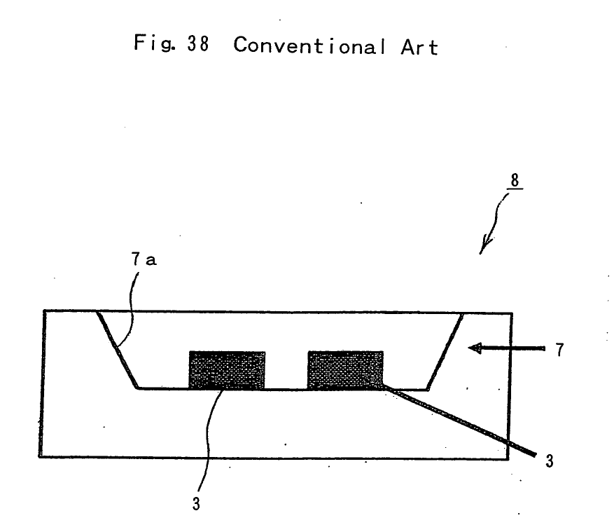

FIG. 39 is a schematic cross-sectional view showing a mounting state of the conventional LED shown in FIG. 38.

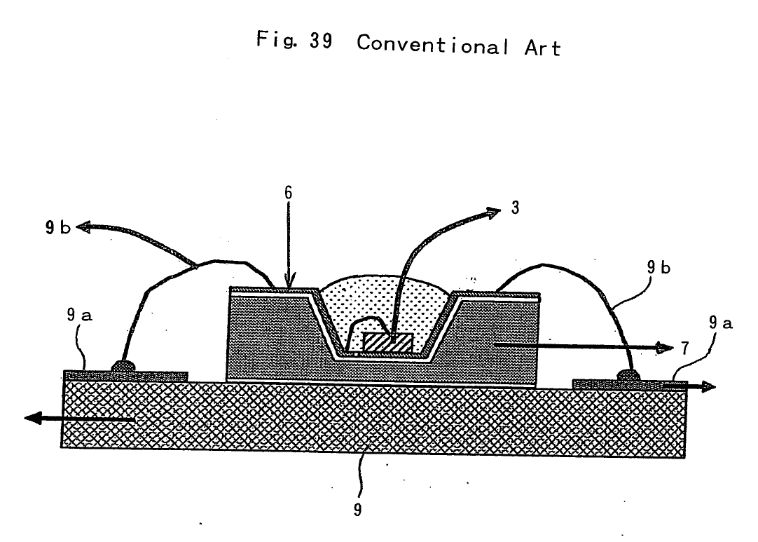

### DETAILED DESCRIPTION OF PREFERRED EMBODIMENTS

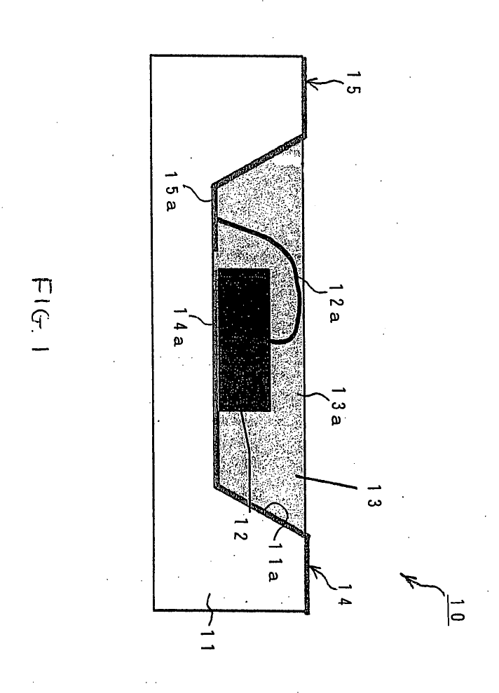

Exemplary embodiments of the invention will now be described in detail with reference to FIGS. 1 to 33.

It should be noted that, although certain technical features are described with respect to the various embodiments, because the embodiments are specific examples of the invention, the scope of the invention is not limited to these embodiments.

### First Embodiment

FIG. 1 shows the configuration of a first embodiment of an LED made in accordance with the principles of the invention.

As shown in FIG. 1, an LED 10 is configured by a silicon substrate 11, an LED chip 12 mounted inside a horn 11a formed as a concave recessed portion in the silicon substrate 11, and a resin mold 13 including a resin material filling the inside of the horn 11a.

The silicon substrate 11 is flatly formed so that the surface thereof forms a (100) surface.

The silicon substrate 11 is disposed with the horn 11a formed by the concave recessed portion from the surface to an intermediate height.

The horn 11a is formed, for example, by anisotropic etching with TMAH so that the side surfaces thereof form (111) surfaces.

It should be noted that, because the side surfaces of the horn 1I a are (111) surfaces, the angle of inclination of the side surfaces with respect to the bottom surface can be set to 54.7 degrees.

In this case, the horn 11a is machined to have an appropriate depth on the basis of time management of the etching process, and the bottom surface of the horn 1I a can be formed to approach as much as possible the bottom surface of the silicon substrate 11—i.e., the thickness of the silicon substrate 11 at the bottom surface of the horn 11a can be thinned as much as possible—so that it is possible to reduce thermal resistance.

Additionally, the silicon substrate 11 is disposed with a pair of electrodes 14 and 15 that extend in FIG. 1 from the bottom surface of the horn 11a to the surface of the silicon substrate 11 via the left and right side surfaces of the horn 11a.

These electrodes 14 and 15 are formed by, for example, forming a thin metal film on the surface of the silicon substrate 11 in which the horn 11a is formed, and then pattern-etching the thin metal film.

Here, the electrode 14 is disposed with a chip mount portion 14a disposed in a center region of the bottom surface of the horn 11a. The pattern of the chip mount portion 14a has a shape that is identical to the shape of a terminal portion of the LED chip 12 to be attached thereto or a shape that is identical to part of the outer contour line thereof. The chip mount portion 14a is also one where self-alignment, in which the pattern and the terminal portion are made to move by the surface tension of the solder melting the floating LED chip 12 so that the pattern and the terminal portion are aligned, can be conducted. The other electrode 15 is disposed with a connection portion 15a that is adjacent to the chip mount portion 14a at the bottom surface of the horn 11a.

Moreover, in this case, both electrodes 14 and 15 are formed so that the surfaces thereof are mirror surfaces at least at regions of the side surfaces. It should be noted that both electrodes 14 and 15 may also be disposed with separate mirror surfaces at the surfaces thereof at least at the regions of the side surfaces.

The LED chip 12 can be an LED chip of a publicly known configuration that emits, for example, blue light. The LED chip 12 can be disposed with electrode portions not shown at the upper surface and the lower surface thereof, mounted on the bottom surface of the horn 11a of the silicon substrate 11, and die-bonded to the chip mount portion 14a of the electrode 14, whereby the electrode portion at the lower surface can be electrically connected to the chip mount portion 14a and the electrode portion at the upper surface can be electrically connected to the connection portion 15a of the other electrode 15 by a bonding wire 12a such as a gold wire.

The resin mold 13 is configured by a translucent resin material such as epoxy resin, and granular phosphors 13a are mixed into the translucent resin material.

Thus, after the inside of the horn 11a of the silicon substrate 11 is filled with the resin mold 13 and the resin mold 13 is hardened, the granular phosphors 13a are dispersed inside.

Here, the granular phosphors 13a are phosphors that emit, for example, yellow excitation light with respect to the color of the emission light of the LED chip 12. Thus, the phosphors 13a are excited by the blue light from the LED chip 12, the phosphors 13a emit yellow excitation light, the yellow excitation light is mixed with the blue light from the LED chip 12, and white light is emitted to the outside.

The LED 10 according to the embodiment of the invention is configured as described above and can be fabricated as follows on the basis of a fabrication method in accordance with the principles of the invention.

Namely, first the horn 11a can be formed by anisotropic etching with respect to the surface that is the (100) surface of the flat silicon substrate 11. In this case, for example, TMAH (tetramethyl ammonium hydride) is used as the etching agent.

With TMAH, the undercut resulting from the etching is relatively large and dimensional control is difficult, but there are the advantages that there is little mask damage, an oxidized film mask is usable and the consistency with CMOS is excellent. In contrast, when KOH is used as the etching agent, the undercut is small but the consistency with CMOS is poor.

It should be noted that the side surfaces of the horn 11a formed by such etching become inclined surfaces with an inclination angle of 54.7 degrees as (111) surfaces.

Also, a horn 11a with a desired depth can be formed by appropriately managing the etching time.

Before the electrodes of the next step are formed, the Si surface is covered and insulated with a thin SiO₂ layer by thermal oxidation.

Next, a thin metal film that will serve as the electrodes is formed across the entire surface of the silicon substrate 11 in which the horn 11a is formed, and thereafter this thin metal film is pattern-etched, whereby the electrodes 14 and 15 are formed. At this time, the surfaces of the electrodes 14 and 15 are formed as mirror surfaces by forming, by sputtering or deposition, a thin film including a material with a high reflectivity, such as aluminum or silver.

Next, the LED chip 12 is mounted on and die-bonded to the chip mount portion 14a of the electrode 14, and the electrode portion of the surface of the LED chip 12 is wire-bonded to the connection portion 15a of the other electrode 15 by the bonding wire 12a.

Thereafter, the inside of the horn 11a is filled with the resin material in which the granular phosphors 13a are mixed in, and the resin material is hardened. Thus, the resin mold 13 is formed inside the horn 11a. Thus, the LED 10 is completed.

According to the LED 10 fabricated in this manner, electricity is supplied from the outside to the LED chip 12 via the electrodes 14 and 15, whereby the LED chip 12 is driven.

Then, light L emitted from the LED chip 12 is directly reflected or reflected with high reflectivity by the surfaces of the electrodes 14 and 15 formed as mirror surfaces at the bottom surface and the side surfaces of the horn 11a of the silicon substrate 11. The light L strikes the phosphors 13a inside the resin mold 13 and excites the phosphors 13a. Thus, excitation light is emitted from the phosphors 13a, is mixed with the blue light from the LED chip 12, and is emitted upward via the resin mold 13 as white light.

In this case, because the LED chip 12 is mounted on the silicon substrate 11 having a high thermal conductivity of 150 W/m·k, heat generated by the LED chip 12 at the time the LED chip 12 is driven is efficiently dissipated via the silicon substrate 11.

Thus, a rise in the temperature of the LED chip 12 is suppressed and the light emission efficiency of the LED chip 12 does not drop due to the heat, whereby the emitted light beams are not reduced by the heat of the LED chip and the lifespan does not drop.

Also, because the electrodes 14 and 15 for electrical connection to the LED chip 12 are formed by patterning, it is possible to mutually connect the LED chips 12 in series when fabricating a multichip LED, and the current does not become concentrated at the LED chip 12 whose Vf is low.

Moreover, because the side surfaces of the horn 11a are formed as (111) surfaces, the side surfaces of the horn 11a are formed as excellent mirror surfaces that cannot be obtained by ordinary machining, such as cutting or punching a metal material or resin molding.

Moreover, it is possible to integrally configure another semiconductor device such as an IC by an existing semiconductor fabrication process on the silicon substrate 11, which can be acquired relatively inexpensively. Thus, it becomes possible to incorporate a drive circuit for conducting lighting and blinking of the LED chip 12, and the LED 10 can be configured compactly including the drive circuit.

In this manner, according to the LED 10, because the LED 10 uses the silicon substrate 11, the heat emitted by the LED chip 12 is efficiently dissipated, the LED 10 can be easily fabricated as a multichip LED due to the electrodes 14 and 15 formed by patterning, and it is possible to mutually connect the LED chips 12 in series, whereby current concentration at the LED chip 12 whose Vf is low resulting from variations can be avoided.

Also, because the LED 10 can be easily fabricated using an existing semiconductor fabrication device, special capital expenditures are unnecessary, and the LED 10 can be fabricated at a relatively low cost.

### Second Embodiment

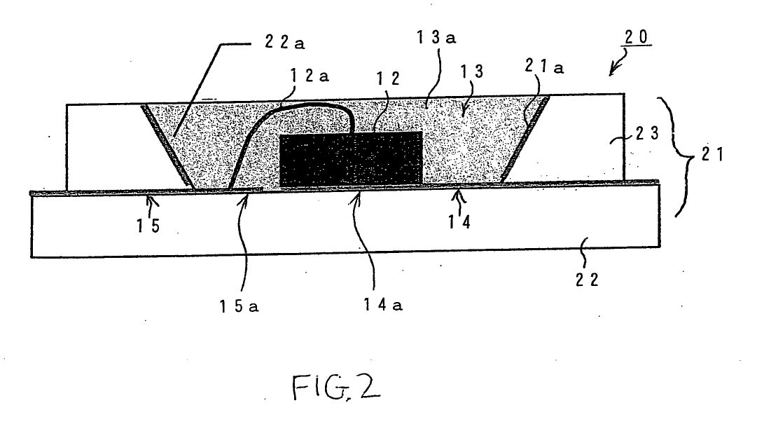

FIG. 2 shows the configuration of a second embodiment of an LED made in accordance with the principles of the invention.

As shown in FIG. 2, because an LED 20 has substantially the same configuration as that of the LED 10 shown in FIG. 1, the same reference numerals will be given to the same constituent elements and description of those same constituent elements will be omitted.

Namely, the LED 20 is configured by a silicon substrate 21, the LED chip 12 mounted inside a horn 21a formed as a concave recessed portion in the silicon substrate 21, and the resin mold 13 including a resin material filling the inside of the horn 21a.

Here, the silicon substrate 21 is configured by being laminated in two layers.

Namely, the silicon substrate 21 is configured by a lower first substrate 22 and an upper second substrate 23.

The first substrate 22 is configured by a flat silicon substrate, and the electrodes 14 and 15 are formed on the surface thereof by patterning a thin metal film. In this case, the electrodes 14 and 15 extend sideways along the surface of the first substrate 22, i.e., through the inside of the silicon substrate 21.

In contrast, the second substrate 23 is flatly formed, so that the surface thereof becomes a (100) surface), and is disposed with a horn 21a formed so as to vertically penetrate the second substrate 21.

Similar to the horn 11a of the LED 10, the horn 21a is formed by, for example, anisotropic etching with TMAH so that the side surfaces thereof become (111) surfaces, and the side surfaces overall are disposed with mirror surfaces. As is publicly known, the mirror surfaces are obtained by forming, by deposition or plating, a thin film of a material with a high reflectivity on the surface of the horn 11a.

The LED 20 of this configuration is fabricated as follows on the basis of a fabrication method in accordance with the principles of the invention.

Namely, first the electrodes 14 and 15 are formed by pattern-etching a thin metal film on the surface of the silicon substrate serving as the first substrate 22.

In tandem with this, the horn 21a is formed by anisotropic etching of the surface that is the (100) surface of the silicon substrate serving as the second substrate 23. In this case, because the horn 21a vertically penetrates the second substrate 23, it is not necessary to set with high precision the depth of the horn 21a, so that time management of the etching process becomes easy.

Next, the mirror surface is formed by deposition or plating on the side surfaces of the horn 21a of the second substrate 23, and thereafter the second substrate 23 is adhered to the first substrate 22.

Next, the LED chip 12 is mounted on and die-bonded to the chip mount portion 14a of the electrode 14 exposed to the bottom surface of the horn 21a, and the electrode portion of the surface of the LED chip 12 is wire-bonded to the connection portion 15a of the other electrode 15 by the bonding wire 12a.

Thereafter, the inside of the horn 21a is filled with the resin material in which the granular phosphors 13a are mixed in, and the resin material is hardened. Thus, the resin mold 13 is formed inside the horn 21a. It should be noted that, before the electrodes are formed, the Si surface is covered and insulated with a thin SiO₂ layer by thermal oxidation resulting from sputtering. Thus, the LED 20 is completed.

According to the LED 20 fabricated in this manner, the LED 20 acts in the same manner as the LED 10 shown in FIG. 1, and the silicon substrate 21 is configured in two layers, whereby it becomes possible to form a complex wiring pattern on the surface of the first substrate 22. Also, because the mirror surface is formed across the entire inner surface of the horn 21a of the second substrate 23, the emission efficiency of light to the outside is improved.

### Third Embodiment

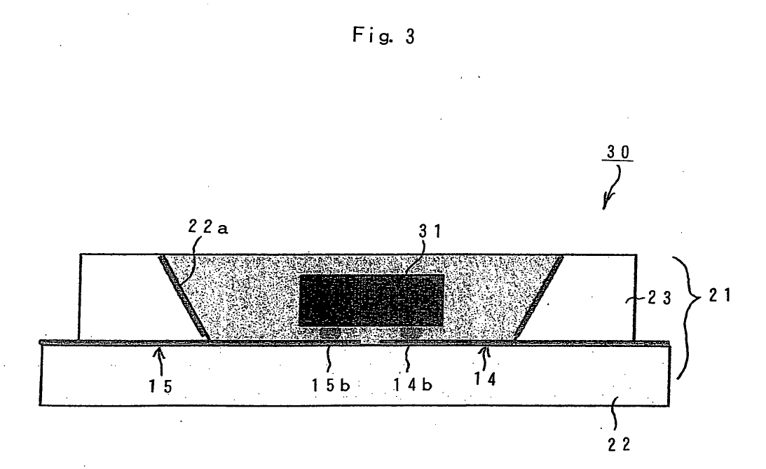

FIG. 3 shows the configuration of a third embodiment of an LED made in accordance with the principles of the invention.

As shown in FIG. 3, because an LED 30 has substantially the same configuration as that of the LED 20 shown in FIG. 2, the same reference numerals will be given to the same constituent elements and description of those same constituent elements will be omitted.

The LED 30 is formed so as to be disposed with chip mount portions 14b and 15b, where the electrodes 14 and 15 mutually face each other with an interval disposed therebetween, in the vicinity of the center of the upper surface of the first substrate 22.

Additionally, a so-called flip chip type LED chip 31 is mounted on and electrically connected to the tops of the chip mount portions 14b and 15b so as to ride on the electrode portions disposed at both side edges of the undersurface thereof.

According to the LED 30 of this configuration, the LED 30 acts in the same manner as the LED 20 shown in FIG. 2.

### Fourth Embodiment

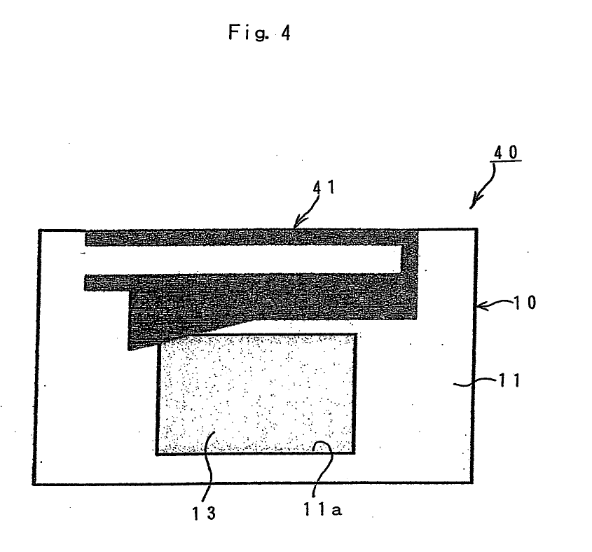

FIG. 4 shows the configuration of a fourth embodiment of an LED made in accordance with the principles of the invention.

As shown in FIG. 4, an LED 40 is one where a thermoelectric bimorph actuator is configured as an actuator adjacent to the horn 11a above the silicon substrate 11 with respect to the LED 10 according to FIG. 1.

The thermoelectric bimorph actuator 41 itself has a publicly known configuration and is configured by etching using the so-called MEMS technique in a semiconductor fabrication process on the silicon substrate 11.

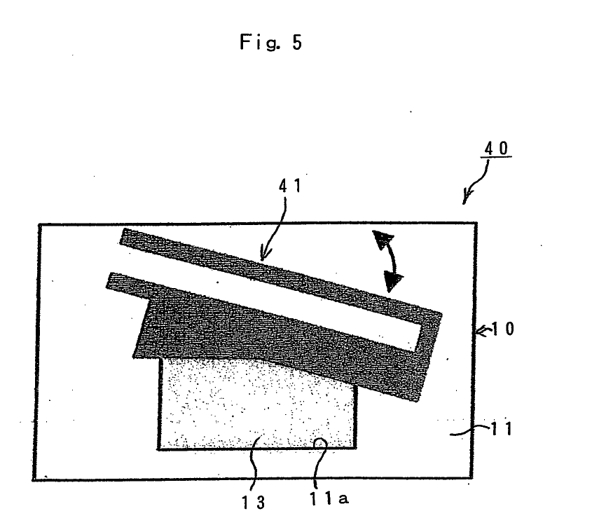

Additionally, the thermoelectric bimorph actuator 41 is supplied with electricity via electrodes not shown, whereby, as shown in FIG. 5, it is displaced on the semiconductor substrate 11 and covers part of the upper surface of the horn 11a.

According to the LED 40 of this configuration, light is emitted to the outside from the horn 11a of the silicon substrate 11 in a manner similar to the case of the LED 10. When the thermoelectric bimorph actuator 41 is not operating, light is emitted to the outside from the entire light-emitting portion resulting from the open portion of the upper end of the horn 11a, and when the thermoelectric bimorph actuator 41 is operating, part of the light-emitting portion is blocked off by the thermoelectric bimorph actuator 41, so that it is possible to change the shape of the light-emitting portion. Thus, for example, when the LED 40 is used as the light source of an automobile headlight, switching of the high beam and the low beam becomes possible.

It should be noted that changing the shape of the light-emitting portion resulting from the open portion of the upper end of the horn 11a can also be realized by another type of actuator that can be configured on the silicon substrate 11.

### Fifth Embodiment

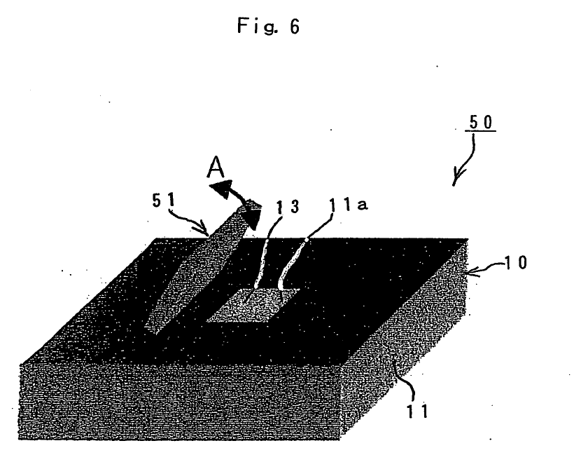

FIG. 6 shows a fifth embodiment of an LED made in accordance with the principles of the invention.

As shown in FIG. 6, an LED 50 is one where a vertical comb-type electrostatic actuator 51 is configured as an actuator adjacent to the horn 11a on the silicon substrate 11 with respect to the LED 10 according to FIG. 1.

The vertical comb-type electrostatic actuator 51 itself has a publicly known configuration as a “Vertical Comb” and is configured by etching using the so-called MEMS technique in a semiconductor fabrication process on the silicon substrate 11.

Additionally, the vertical comb-type electrostatic actuator 51 is supplied with electricity via electrodes not shown, whereby, as shown by arrow A in FIG. 6, it swings above the semiconductor substrate 11 and some of the light beams emitted from the upper surface of the horn 11a are blocked.

According to the LED 50 of this configuration, light is emitted to the outside from the horn 11a of the silicon substrate 11 in a manner similar to the case of the LED 10. Due to the vertical comb-type electrostatic actuator 51, part of the light emitted from the entire light-emitting portion resulting from the open portion of the upper end of the horn 11a is selectively blocked off, whereby the light distribution pattern is changed. Thus, for example, when the LED 50 is used as the light source of an automobile headlight, a so-called AFS function can be realized.

It should be noted that changing the shape of the light-emitting portion resulting from the open portion of the upper end of the horn 11a can also be realized by another type of actuator that can be configured on the silicon substrate 11.

### Sixth Embodiment

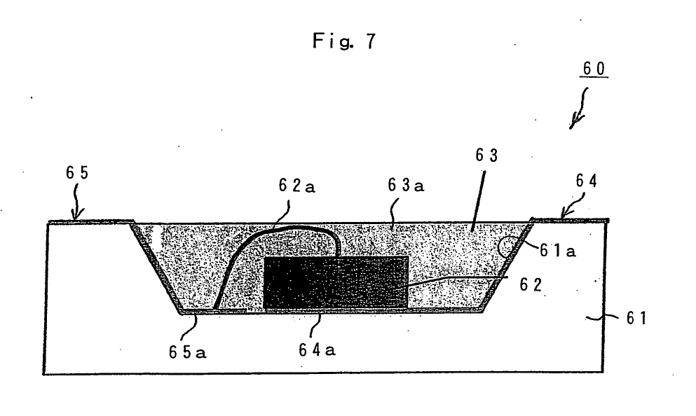

FIG. 7 shows the configuration of a sixth embodiment of an LED made in accordance with the principles of the invention.

As shown in FIG. 7, an LED 60 is configured by a silicon substrate 61, an LED chip 62 mounted inside a horn 61a formed as a concave recessed portion in the silicon substrate 61, and a resin mold 63 including a resin material filling the inside of the horn 61a.

The silicon substrate 61 is flatly formed so that the surface thereof forms a (100) surface.

The silicon substrate 61 is disposed with the horn 61a formed by the concave recessed portion from the surface to a height above a lower surface so as not to pass through completely the substrate 61.

The horn 61a is formed, for example, by liquid phase crystal anisotropic etching with TMAH so that the side surfaces thereof form (111) surfaces.

It should be noted that, because the side surfaces of the horn 61a are (111) surfaces, the angle of inclination of the side surfaces with respect to the bottom surface is set to 54.7 degrees.

In this case, the horn 61a is machined to have an appropriate depth on the basis of time management of the etching process, and the bottom surface of the horn 61a can be formed to approach as much as possible the bottom surface of the silicon substrate 61—i.e., the thickness of the silicon substrate 61 at the bottom surface of the horn 61a can be thinned as much as possible—so that it is possible to reduce thermal resistance.

Additionally, the silicon substrate 61 is disposed with a pair of electrodes 64 and 65 that extend in FIG. 7 from the bottom surface of the horn 61a to the surface of the silicon substrate 61 via the left and right side surfaces of the horn 61a.

These electrodes 64 and 65 are formed by, for example, forming a thin metal film on the surface of the silicon substrate 61 in which the horn 61a has been formed, and then pattern-etching the thin metal film.

Here, the electrode 64 is disposed with a chip mount portion 64a disposed in a center region of the bottom surface of the horn 61a. The pattern of the chip mount portion 64a has a shape that is identical to the shape of a terminal portion of the LED chip 62 to be attached thereto or a shape that is identical to part of the outer contour line thereof. The chip mount portion 64a is also one where self-alignment, in which the pattern and the terminal portion are made to move by the surface tension of the solder melting the floating LED chip 62 so that the pattern and the terminal portion are aligned, can be conducted. Another electrode 65 is disposed with a connection portion 65a that is adjacent to the chip mount portion 64a at the bottom surface of the horn 61a.

Moreover, in this case, both electrodes 64 and 65 are formed so that the surfaces thereof are mirror surfaces at least at regions of the side surfaces. It should be noted that both electrodes 64 and 65 may also be disposed with separate mirror surfaces at the surfaces thereof at least at the regions of the side surfaces.

The LED chip 62 is an LED chip of a publicly known configuration that emits, for example, blue light. The LED chip 62 is disposed with electrode portions not shown at the upper surface and the lower surface thereof, is mounted on the bottom surface of the horn 61a of the silicon substrate 61, and is die-bonded to the chip mount portion 64a of the electrode 64, whereby the electrode portion at the lower surface is electrically connected to the chip mount portion 64a and the electrode portion at the upper surface is electrically connected to the connection portion 65a of the other electrode 65 by a bonding wire 62a such as a gold wire.

The resin mold 63 is configured by a translucent resin material such as epoxy resin, and granular phosphors 63a are mixed into the translucent resin material.

Thus, after the inside of the horn 61a of the silicon substrate 61 is filled with the resin mold 63 and the resin mold 63 is hardened, the granular phosphors 63a are dispersed inside.

Here, the granular phosphors 63a are phosphors that emit, for example, yellow excitation light with respect to the color of the emission light of the LED chip 62. Thus, the phosphors 63a are excited by the blue light from the LED chip 62, the phosphors 63a emit yellow excitation light, the yellow excitation light is mixed with the blue light from the LED chip 62, and white light is emitted to the outside.

The LED 60 according to the embodiment of the invention is configured as described above and is fabricated as follows on the basis of a fabrication method made in accordance with the principles of the invention.

Namely, first the horn 61a is formed by liquid phase crystal anisotropic etching with respect to the surface that is the (100) surface of the flat silicon substrate 61. In this case, for example, TMAH (tetramethyl ammonium hydride) is used as the etching agent.

With TMAH, the undercut resulting from the etching is relatively large and dimensional control is difficult, but there are the advantages that there is little mask damage, an oxidized film mask is usable and the consistency with CMOS is excellent. In contrast, when KOH is used as the etching agent, the undercut is small but the consistency with CMOS is poor.

It should be noted that the side surfaces of the horn 61a formed by such etching become inclined surfaces with an inclination angle of 54.7 degrees as (111) surfaces.

Also, a horn 61a with a desired depth can be formed by appropriately managing the etching time.

Before the electrodes of the next step are formed, the Si surface is covered and insulated with a thin SiO₂ layer or Si₃N₄ layer by, for example, sputtering method, CVD method or thermal oxidation method.

Next, a thin metal film that will serve as the electrodes is formed across the entire surface of the silicon substrate 61 in which the horn 61a is formed, and thereafter this thin metal film is pattern-etched, whereby the electrodes 64 and 65 are formed. For the pattern etching method, a method for forming a uniform resist film for a three dimensional form can be used such as a electroformed resist, a sprayed resist, or the like. At this time, the surfaces of the electrodes 64 and 65 are formed as mirror surfaces by forming, by sputtering, vacuum evaporation, or electroplating, a thin film including a material with a high reflectivity, such as aluminum or silver.

Next, the LED chip 62 is mounted on and die-bonded to the chip mount portion 64a of the electrode 64, and the electrode portion of the surface of the LED chip 62 is wire-bonded to the connection portion 65a of the other electrode 65 by the bonding wire 62a.

Thereafter, the inside of the horn 61a is filled with the resin material in which the granular phosphors 63a are mixed in, and the resin material is hardened. Thus, the resin mold 63 is formed inside the horn 61a. Thus, the LED 60 is completed.

According to the LED 60 fabricated in this manner, electricity is supplied from the outside to the LED chip 62 via the electrodes 64 and 65, whereby the LED chip 62 is driven.

Then, light L emitted from the LED chip 62 is directly reflected or reflected with high reflectivity by the surfaces of the electrodes 64 and 65 formed as mirror surfaces at the bottom surface and the side surfaces of the horn 61a of the silicon substrate 61. The light L strikes the phosphors 63a inside the resin mold 63 and excites the phosphors 63a. Thus, excitation light is emitted from the phosphors 63a, is mixed with the blue light from the LED chip 62, and is emitted upward via the resin mold 63 as white light.

In this case, because the LED chip 62 is mounted on the silicon substrate 61 having a high thermal conductivity of 150 W/m·k, heat generated by the LED chip 62 at the time the LED chip 62 is driven is efficiently dissipated via the silicon substrate 61.

Thus, a rise in the temperature of the LED chip 62 is suppressed and the light emission efficiency of the LED chip 62 does not drop due to the heat, whereby the emitted light beams are not reduced by the heat of the LED chip and the lifespan does not drop.

Also, because the electrodes 64 and 65 for electrical connection to the LED chip 62 are formed by patterning, it is possible to mutually connect the LED chips 62 in series when fabricating a multichip LED, and the current does not become concentrated at the LED chip 62 whose Vf is low.

Moreover, because the side surfaces of the horn 61a are formed as (111) surfaces, the side surfaces of the horn 61a are formed as excellent mirror surfaces that cannot be obtained by ordinary machining, such as cutting or punching a metal material or resin molding.

Moreover, it is possible to integrally configure another semiconductor device such as an IC by an existing semiconductor fabrication process on the silicon substrate 61, which can be acquired relatively inexpensively. Thus, it becomes possible to incorporate a drive circuit for conducting lighting and blinking of the LED chip 62, and the LED 60 can be configured compactly including the drive circuit.

In this manner, according to the LED 60, because the LED 60 uses the silicon substrate 61, the heat emitted by the LED chip 62 is efficiently dissipated, the LED 60 can be easily fabricated as a multichip LED due to the electrodes 64 and 65 formed by patterning, and it is possible to mutually connect the LED chips 62 in series, whereby current concentration at the LED chip 62 whose Vf is low resulting from variations can be avoided.

Also, because the LED 60 can be easily fabricated using an existing semiconductor fabrication device, special capital expenditures are unnecessary, and the LED 60 can be fabricated at a relatively low cost.

### Seventh Embodiment

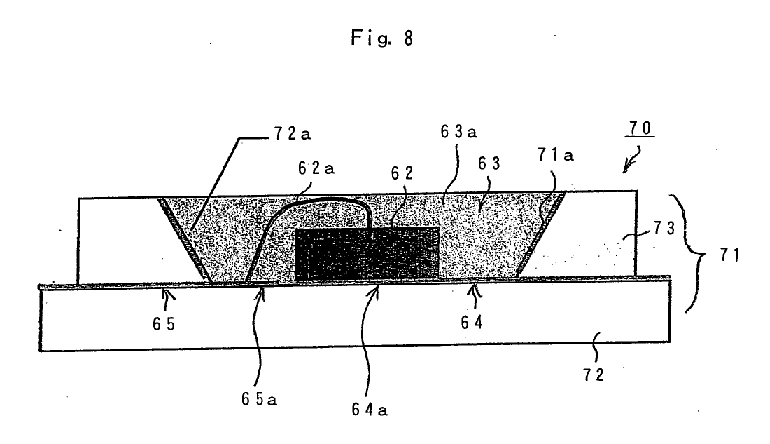

FIG. 8 shows the configuration of a seventh embodiment of an LED made in accordance with the principles of the invention.

As shown in FIG. 8, because an LED 70 has substantially the same configuration as that of the LED 60 shown in FIG. 7, the same reference numerals will be given to the same constituent elements and description of those same constituent elements will be omitted.

Namely, the LED 70 is configured by a silicon substrate 71, the LED chip 62 mounted inside a horn 71a formed as a concave recessed portion in the silicon substrate 71, and the resin mold 63 including a resin material filling the inside of the horn 71a.

Here, the silicon substrate 71 is configured by being laminated in two layers.

Namely, the silicon substrate 71 is configured by a lower first substrate 72 and an upper second substrate 73.

The first substrate 72 is configured by a flat silicon substrate, and the electrodes 64 and 65 are formed on the surface thereof by patterning a thin metal film. In this case, the electrodes 64 and 65 extend sideways along the surface of the first substrate 72, i.e., through the inside of the silicon substrate 71.

In contrast, the second substrate 73 is flatly formed, so that the surface thereof becomes a (100) surface, and is disposed with a horn 71a formed so as to vertically penetrate the second substrate 71.

Similar to the horn 61a of the LED 60, the horn 71a is formed by, for example, liquid phase crystal anisotropic etching with TMAH so that the side surfaces thereof become (111) surfaces, and the side surfaces overall are disposed with mirror surfaces. As is publicly known, the mirror surfaces are obtained by forming a thin film of a material with a high reflectivity on the surface of the horn 11a by deposition or plating.

The LED 70 of this configuration is fabricated as follows on the basis of a fabrication method in accordance with the principles of the invention.

Namely, first the electrodes 64 and 65 are formed by pattern-etching a thin metal film on the surface of the silicon substrate serving as the first substrate 72.

In tandem with this, the horn 71a is formed by liquid phase crystal anisotropic etching of the surface that is the (100) surface of the silicon substrate serving as the second substrate 73. In this case, because the horn 71a vertically penetrates the second substrate 73, it is not necessary to set with high precision the depth of the horn 71a, so that time management of the etching process becomes easy.

Next, the mirror surface is formed by deposition or plating on the side surfaces of the horn 71a of the second substrate 73, and thereafter the second substrate 73 is adhered to the first substrate 72.

Next, the LED chip 62 is mounted on and die-bonded to the chip mount portion 64a of the electrode 64 exposed to the bottom surface of the horn 71a, and the electrode portion of the surface of the LED chip 62 is wire-bonded to the connection portion 65a of the other electrode 65 by the bonding wire 62a.

Thereafter, the inside of the horn 71a is filled with the resin material in which the granular phosphors 63a are mixed in, and the resin material is hardened. Thus, the resin mold 63 is formed inside the horn 71a. It should be noted that, before the electrodes are formed, the Si surface is covered and insulated with a thin SiO₂ layer or Si₃N₄ layer by, for example, sputtering method, CVD method or thermal oxidation method. Thus, the LED 70 is completed.

According to the LED 70 fabricated in this manner, the LED 70 acts in the same manner as the LED 60 shown in FIG. 7, and the silicon substrate 71 is configured in two layers, whereby it becomes possible to form a complex wiring pattern on the surface of the first substrate 72. Also, because the mirror surface is formed across the entire inner surface of the horn 71a of the second substrate 73, the emission efficiency of light to the outside is improved.

### Eighth Embodiment

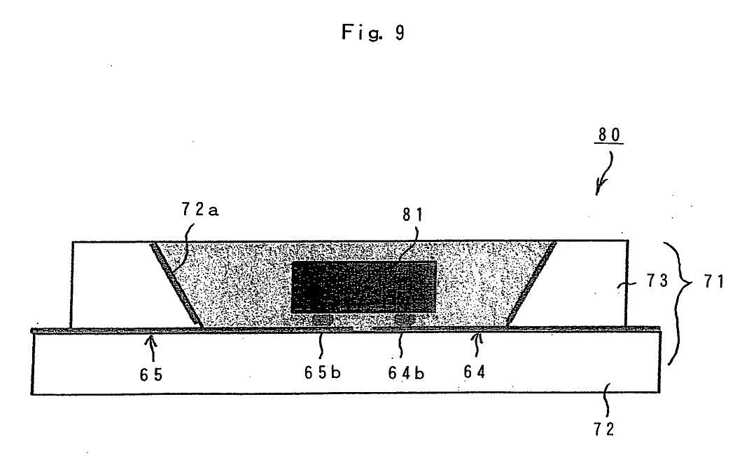

FIG. 9 shows the configuration of an eighth embodiment of an LED made in accordance with the principles of the invention.

As shown in FIG. 9, because an LED 80 has substantially the same configuration as that of the LED 70 shown in FIG. 8, the same reference numerals will be given to the same constituent elements and description of those same constituent elements will be omitted.

The LED 80 is formed so as to be disposed with chip mount portions 64b and 65b, where the electrodes 64 and 65 mutually face each other with an interval disposed therebetween, in the vicinity of the center of the upper surface of the first substrate 72.

Additionally, a so-called flip chip type LED chip 81 is mounted on and electrically connected to the tops of the chip mount portions 64b and 65b so as to ride on the electrode portions disposed at both side edges of the undersurface thereof.

According to the LED 80 of this configuration, the LED 80 acts in the same manner as the LED 70 shown in FIG. 8.

### Ninth Embodiment

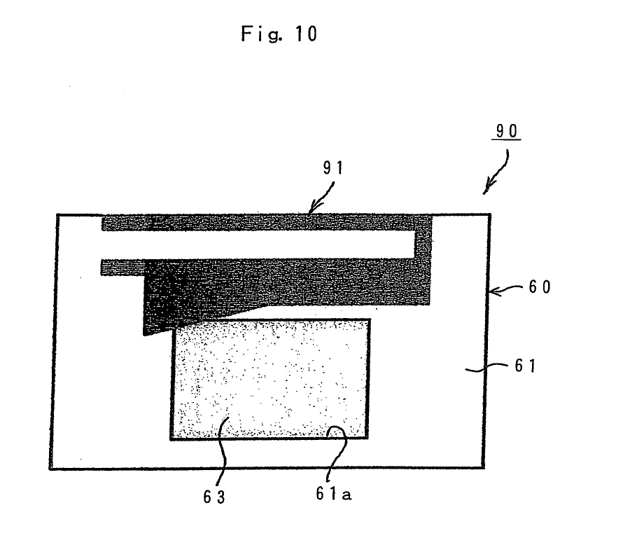

FIG. 10 shows the configuration of a ninth embodiment of an LED made in accordance with the principles of the invention.

As shown in FIG. 10, an LED 90 is one where a thermoelectric bimorph actuator is configured as an actuator adjacent to the horn 61a above the silicon substrate 61 with respect to the LED 60 according to FIG. 7.

The thermoelectric bimorph actuator 91 itself has a publicly known configuration and is configured by etching using the so-called MEMS technique in a semiconductor fabrication process on the silicon substrate 61.

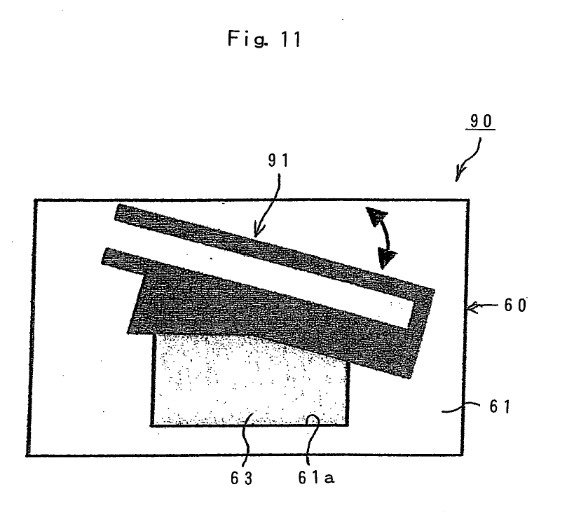

Additionally, the thermoelectric bimorph actuator 91 is supplied with electricity via electrodes not shown, whereby, as shown in FIG. 11, it is displaced on the semiconductor substrate 61 and covers part of the upper surface of the horn 61a.

According to the LED 90 of this configuration, light is emitted to the outside from the horn 61a of the silicon substrate 61 in a manner similar to the case of the LED 60. When the thermoelectric bimorph actuator 91 is not operating, light is emitted to the outside from the entire light-emitting portion resulting from the open portion of the upper end of the horn 61a, and when the thermoelectric bimorph actuator 91 is operating, part of the light-emitting portion is blocked off by the thermoelectric bimorph actuator 91, so that it is possible to change the shape of the light-emitting portion. Thus, for example, when the LED 90 is used as the light source of an automobile headlight, switching of the high beam and the low beam becomes possible.

It should be noted that changing the shape of the light-emitting portion resulting from the open portion of the upper end of the horn 61a can also be realized by another type of actuator that can be configured on the silicon substrate 61.

### Tenth Embodiment

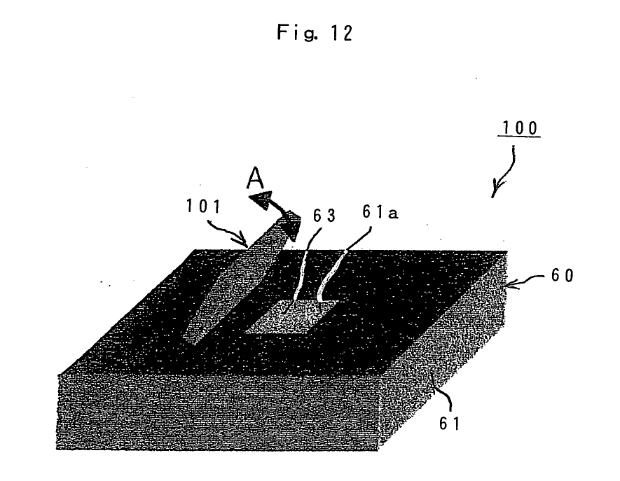

FIG. 12 shows the configuration of a tenth embodiment of an LED made in accordance with the principles of the invention.

As shown in FIG. 12, an LED 100 is one where a vertical comb-type electrostatic actuator 101 is configured as an actuator adjacent to the horn 61a on the silicon substrate 61 with respect to the LED 60 according to FIG. 7.

The vertical comb-type electrostatic actuator 101 itself has a publicly known configuration as a “Vertical Comb” and is configured by etching using the so-called MEMS technique in a semiconductor fabrication process on the silicon substrate 61.

Additionally, the vertical comb-type electrostatic actuator 101 is supplied with electricity via electrodes not shown, whereby, as shown by arrow A in FIG. 12, it swings above the semiconductor substrate 61 and some of the light beams emitted from the upper surface of the horn 61a are blocked.

According to the LED 100 of this configuration, light is emitted to the outside from the horn 61a of the silicon substrate 61 in a manner similar to the case of the LED 60. Due to the vertical comb-type electrostatic actuator 101, part of the light emitted from the entire light-emitting portion resulting from the open portion of the upper end of the horn 61a is selectively blocked off, whereby the light distribution pattern is changed. Thus, for example, when the LED 100 is used as the light source of an automobile headlight, a so-called AFS function can be realized.

It should be noted that changing the shape of the light-emitting portion resulting from the open portion of the upper end of the horn 11a can also be realized by another type of actuator that can be configured on the silicon substrate 61.

### Eleventh Embodiment

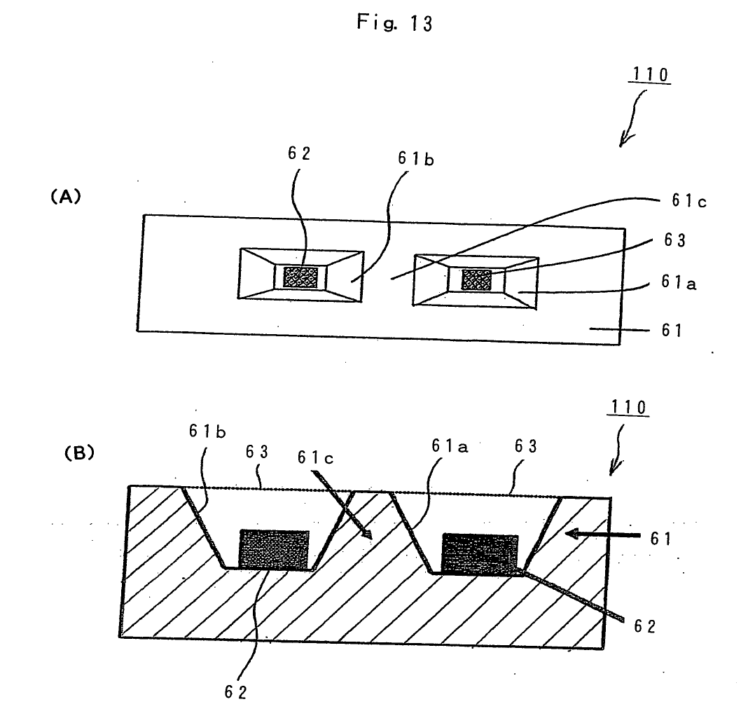

FIG. 13 shows the configuration of an eleventh embodiment of an LED made in accordance with the principles of the invention.

As shown in FIG. 13, because an LED 110 has substantially the same configuration as that of the LED 60 shown in FIG. 7, the same reference numerals will be given to the same constituent elements and description of those same constituent elements will be omitted.

Namely, the LED 110 is configured by a silicon substrate 61, two LED chip 62 mounted inside a horn 61a, 61b formed side by side respectively as a concave recessed portion in the silicon substrate 61, and the resin mold 63 including a resin material filling the inside of the horn 61a, 61b.

Here, the silicon substrate 61 is flatly formed so that the surface thereof forms a (100) surface, and is disposed with the two horn 61a, 61b formed by the concave recessed portion from the surface to an intermediate height.

Similar to the horn 61a of the LED 60, these horns 61a, 61b are formed, for example, by liquid phase crystal anisotropic etching with TMAH so that the side surfaces thereof form (111) surfaces.

Moreover, these horns 61a, 61b are arranged apart from each other, and form a partition wall 61c between those.

This partition wall 61c has a height as same as the upper surface of the silicon substrate 61, and its upper surface is flatly formed. A width of the upper surface is so selected as several μm to several 10 μm.

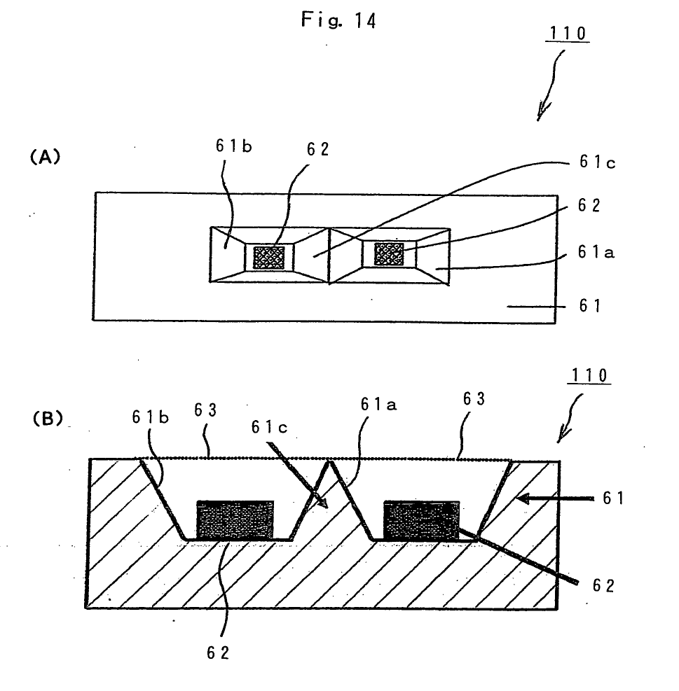

This partition wall 61c may be formed, as shown in FIG. 14, as peaked to provide a crest line at the upper end. Thus, without changing the height of the partition wall 61c, a distance of the LED chips 62 can be reduced.

Additionally, the silicon substrate 61 is disposed with a pair of electrodes (not shown) serving as reflecting mirrors in the bottom surface and side surface of the horn 61a and in the side surface of the partition wall 61c, and these electrodes supply electricity to the LED chips 62, by connecting both of the LED chips 62 in series or in parallel.

These electrodes are formed by, for example, forming a thin metal film such as silver on the surface of the silicon substrate 61 in which the horn 61a is formed, and then pattern-etching the thin metal film.

Moreover, these electrodes extend via the side surfaces of the horn 61a, 61b to the upper surface of the silicon substrate 61, and the upper surface area can be connected electrically to a connecting portion on a mounting board by using a bonding wire, lead wire, soldering or silver-paste.

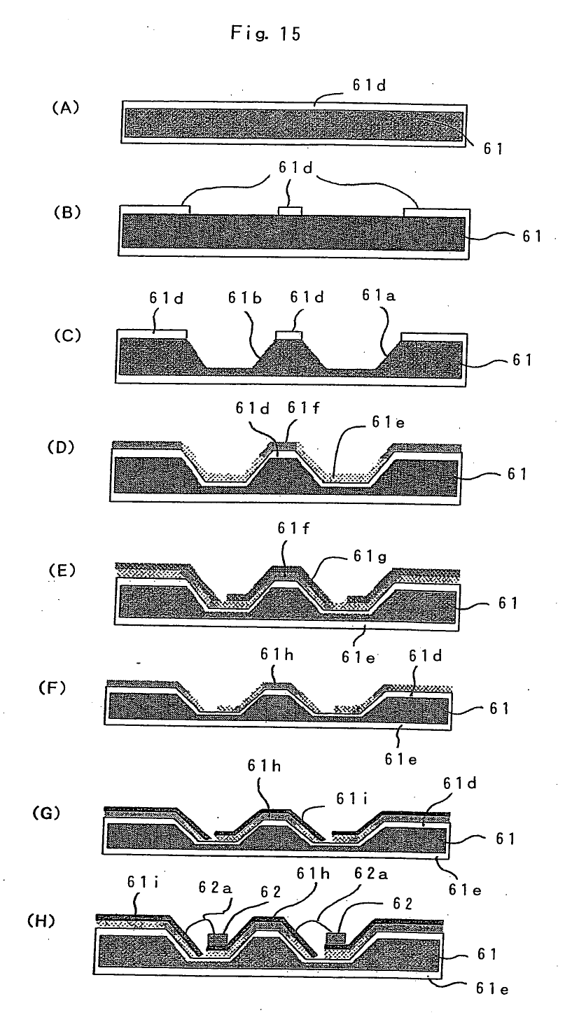

The LED 110 of this configuration is fabricated as follows on the basis of a fabrication method in accordance with the principles of the invention as shown in FIG. 15.

Namely, a silicon substrate 61 of a single crystal silicon wafer with 525 μm thickness is prepared, a (100) surface of which has been flattened by optical polishing process, and on the surface of the silicon substrate 61 is formed a thermal oxidation silicon film 61d with 500 nm thickness by diffusion furnace, as shown in FIG. 15(A).

And, as shown in FIG. 15(B), on the flat surface of the silicon substrate 61 is formed a resist pattern by photolithography method, then the thermal oxidation silicon film 61d is removed selectively by etching of buffered hydrofluoric acid (BHF) so that a pattern of the thermal oxidation silicon film 61d is formed.

Thereafter, as shown in FIG. 15(C), the horn 61a, 61b are formed at the same time by, for example, liquid phase crystal anisotropic etching with TMAH solution, then all of the remaining thermal oxidation silicon film 61d is removed by BHF solution.

Next, shown in FIG. 15(D), on the entire surface of the silicon substrate 61, that including the horn 61a and 61b, is formed again a thermal oxidation silicon film 61e with 500 nm thickness by diffusion furnace so that the entire surface of the silicon substrate 61 is insulated, then on that a electrode film 61f is formed by sputtering method. This electrode film 61f can be formed of Ti with 20 nm thickness and Cu with 200 nm thickness.

Then, as shown in FIG. 15(E), by a electroformed resist or a sprayed resist coating, on the entire surface of the silicon substrate 61, that including the horn 61a and 61b, is applied a resist 61g, then a patterning of the resist 61g is carried out by photolithography method.

Thereafter, as shown in FIG. 15(F), by using the resist pattern 61g as a mask, the electrode film 61f is wet-etched, then a electrode pattern 61h is formed. In this case, the electrode pattern 61h is formed so as to both of the LED chips 12 in series.

Next, as shown in FIG. 15(G), on that are formed a reflecting mirror film 61i that consist of Ni with 5 μm thickness and Ag with 3 μm thickness formed by electro-plating method.

Thereafter, as shown in FIG. 15(H), to the electrode film pattern 61f constructing one electrode formed at the bottom portion of each horn 61a and 61b, the LED chip 62 is mounted on respectively, and die-bonded by solder or eutectic bonding, and the electrode portion of the surface of each LED chip 62 is wire-bonded to the electrode film pattern 61f constructing another electrode by the bonding wire 62a.

Then, the inside of each horn 61a and 61b is filled with the resin material in which the granular phosphors 63a are mixed in, and the resin material is hardened. Thus, the resin mold 63 is formed inside the horn 61a. Thus, the LED 110 is completed.

According to the LED 110 fabricated in this manner, the LED 110 acts in the same manner as the LED 60 shown in FIG. 7, and between the two LED chip 62 is arranged the partition wall 61c, whereby a light absorption among the LED chips 62 is suppressed so that a lost of power of light is reduced.

For example, in the LED using two LED chip 62 respectively of 120 mW power with a bias 3V and 350 mA, supplying the LED with the bias 6V and 350 mA, a twice power, that is, 240 mW power was obtained. It is conjectured that the light absorption among the LED chips 62 is suppressed by the partition wall 61c.

### Twelfth Embodiment

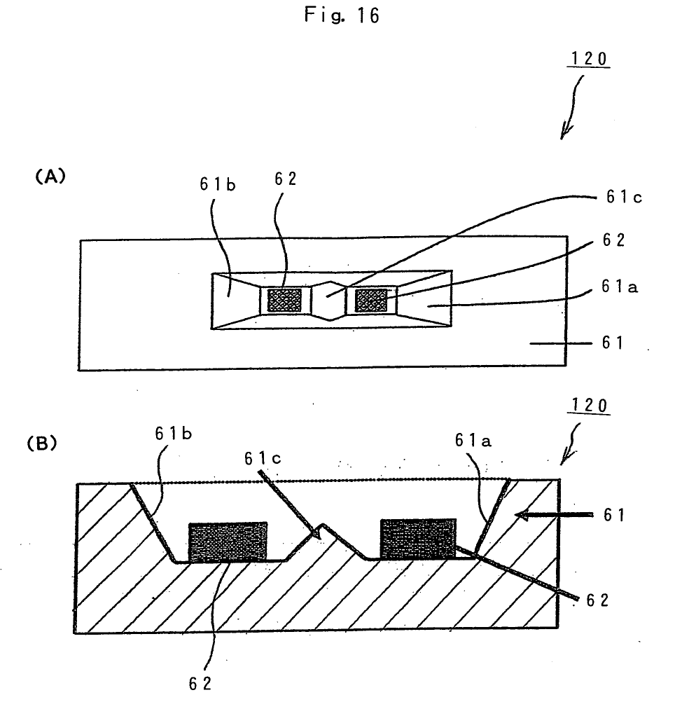

FIG. 16 shows the configuration of a twelfth embodiment of an LED made in accordance with the principles of the invention.

As shown in FIG. 16, because an LED 120 has substantially the same configuration as that of the LED 110 shown in FIG. 13, the same reference numerals will be given to the same constituent elements and description of those same constituent elements will be omitted.

Namely, the LED 120 is configured by a silicon substrate 61, two LED chip 62 mounted inside a horn 61a, 61b formed side by side as a concave recessed portion in the silicon substrate 61, and the resin mold 63 including a resin material filling the inside of the horn 61a, 61b.

In this case, the LED 120 is different from the LED 110 only by that the partition wall 61c has a crest line that is lower than the upper surface of the silicon substrate 61.

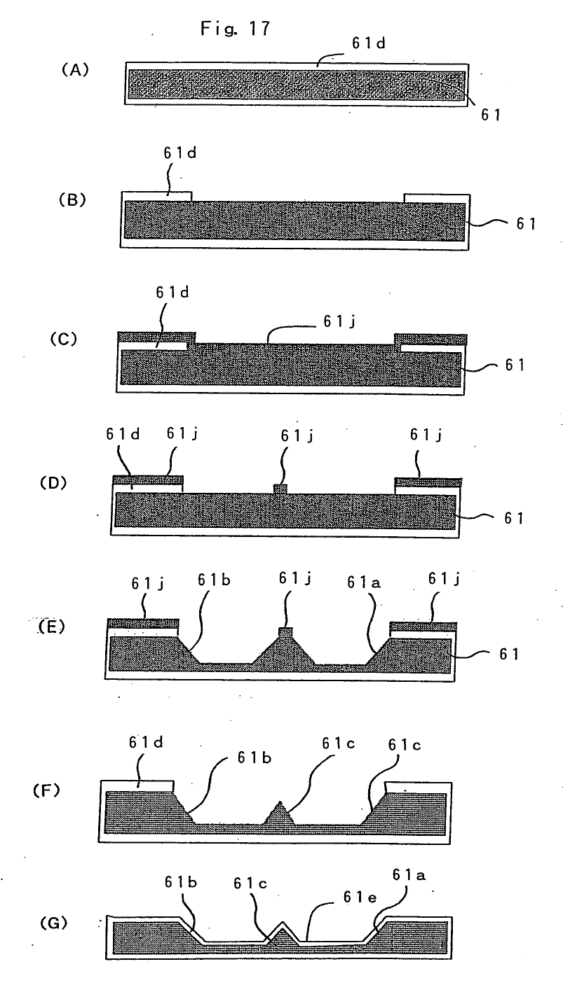

The LED 120 of this configuration is fabricated as follows on the basis of a fabrication method in accordance with the principles of the invention as shown in FIG. 17.

Namely, as shown in FIG. 17(A), on a surface of a silicon substrate 61 is formed a thermal oxidation silicon film 61d with 500 nm thickness by diffusion furnace.

And, as shown in FIG. 17(B), on the flat surface of the silicon substrate 61 is formed a resist pattern by photolithography method, then the thermal oxidation silicon film 61d is removed selectively by etching of BHF solution so that a pattern of the thermal oxidation silicon film 61d is formed.

Then, as shown in FIG. 17(C), on the entire surface of the silicon substrate 61 is formed a silicon nitride film 61j with 200 nm thickness by plasma CVD method.

Next, as shown in FIG. 17(D), using a resist mask(not shown) formed by photolithography method, by thermal phosphoric acid process or plasma etching process, the silicon nitride film 61j is patterned.

Thereafter, as shown in FIG. 17(E), the shallow horn 61a, 61b are formed at the same time by, for example, anisotropic etching with TMAH solution, then, as shown in FIG. 17(F), after washing all of the remaining silicon nitride film 61j is removed by thermal phosphoric acid process or plasma etching process. Then, again by liquid phase crystal anisotropic etching with TMAH solution, a big horn including the horn 61a, 61b separated by the partition wall 61c.

Next, after removing the thermal oxidation silicon film 61d, as shown in FIG. 17(G), on the entire surface of the silicon substrate 61, that including the horn 61a and 61b, is formed again a thermal oxidation silicon film 61e with 500 nm thickness by diffusion furnace so that the entire surface of the silicon substrate 61 is insulated.

Thereafter, similar as in FIGS. 15(D) to (H), on that a electrode film 61f is formed by sputtering, a electrode pattern 61h is formed by pattern etching, and on the electrode pattern 61h is formed a reflecting mirror 61i, then on each electrode pattern 61h in the horn 61a and 61b, the LED chip 62 is respectively die-bonded. And, the surface of each LED chip 62 is wire-bonded to the adjacent electrode pattern 61h, and then the inside of the horn 61a and 61b are filled with the resin material in which the granular phosphors 63a are mixed in, and the resin material is hardened. Thus, the resin mold 63 is formed inside the horn 61a. Thus, the LED 120 is completed.

According to the LED 120 of this configuration, the LED 120 acts in the same manner as the LED 60 shown in FIG. 7, and between the two LED chip 62 is arranged the relatively shallow partition wall 61c, whereby a light absorption among the LED chips 62 is suppressed so that a lost of power of light is reduced.

For this LED 120, by a evaluation as same as that in the LED 110, a twice power of light was obtained, and a light radiation characteristic like a dot light source was obtained by reducing the distance between the LED chips 62.

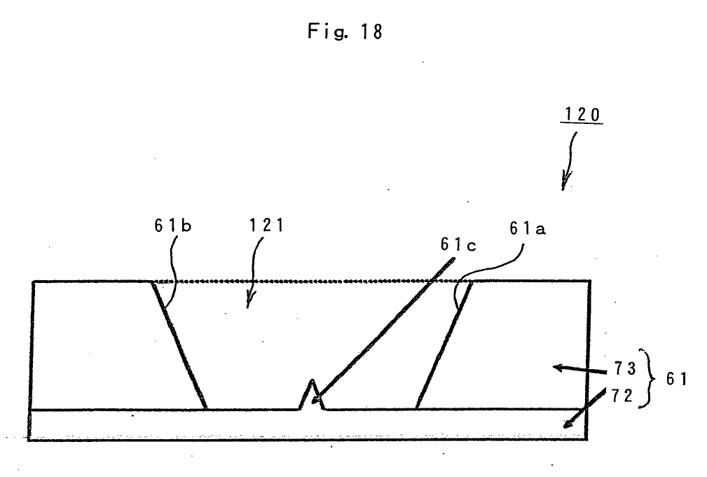

In the above mentioned LED 120, the side surfaces of the partition wall 61c was configured as inclined flat surfaces with an angle of inclination as same as the angle of inclination of the side surfaces of the horn 61a, 61b; however, the silicon substrate 61 may be configured by being laminated in two layers similar to the LED 70 in FIG. 18, a partition wall formed on a lower first substrate 72, and a big horn 121 formed on an upper second substrate 73. In this case, the horn 121 and the partition wall can be separately formed by liquid phase crystal anisotropic etching, so that these are formed with different angles of inclination by controlling the etching suitably.

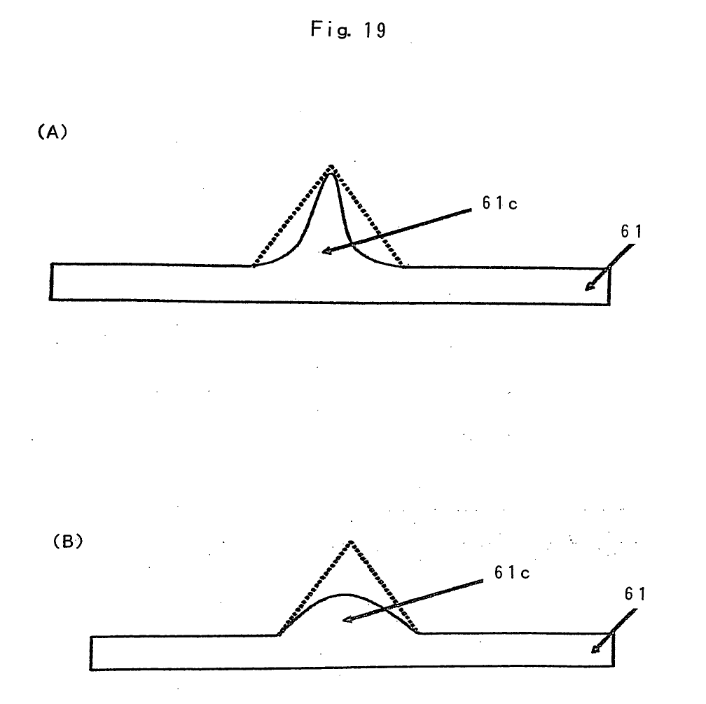

Also, in the above mentioned LED 110 and 120, the side surfaces of the partition wall 61c was configured as inclined flat surfaces; however, the side surfaces of the partition wall 61c may be formed as concave as shown in FIG. 19(A) or as convex as shown in FIG. 19(B), by changing conditions of the anisotropic etching or by exchanging the anisotropic etching for an isotropic etching on the way.

In the case of FIG. 19(B), it is able to set up the height of the partition wall 61c suitably by controlling the etching process.

By various forms of the partition wall 61c, the reflection of light emitted from the LED chip 62 by the side surfaces of the partition wall 61c can be controlled, so that, it is able to realize a desired distribution of brightness and a desired distribution of light by this control of reflection.

In this manner, according to the LED 110 and 120, because the partition wall 61c is arranged between the LED chips 62, the absorption of light among the LED chips 62 can be suppressed, whereby a power of light can be increased.

Also, because the distance between the LED chips 62 can be adjusted suitably by the form of the partition wall 61c, the distance between the LED chips 62 can be reduced more, particularly in the case of the partition wall 61c formed lower than the upper surface of the silicon substrate 61, the distribution characteristic substantially similar a dot light source is obtained, and a mixing effect of the light bundle emitted form each LED chip 62 is raised in the case of mixing the light bundle emitted from each LED chip 62.

And, in the above mentioned LED 110 and 120, two LED chips 62 were mounted; however, three or more LED chips 62 can be mounted, and particularly in the case of LED chips emitting light of primaries, for example, red, green and blue light are mounted, by that a mixing effect of the light bundle emitted form each LED chip 62 is raised, a white light with good color rendering will be obtained.

### Thirteenth Embodiment

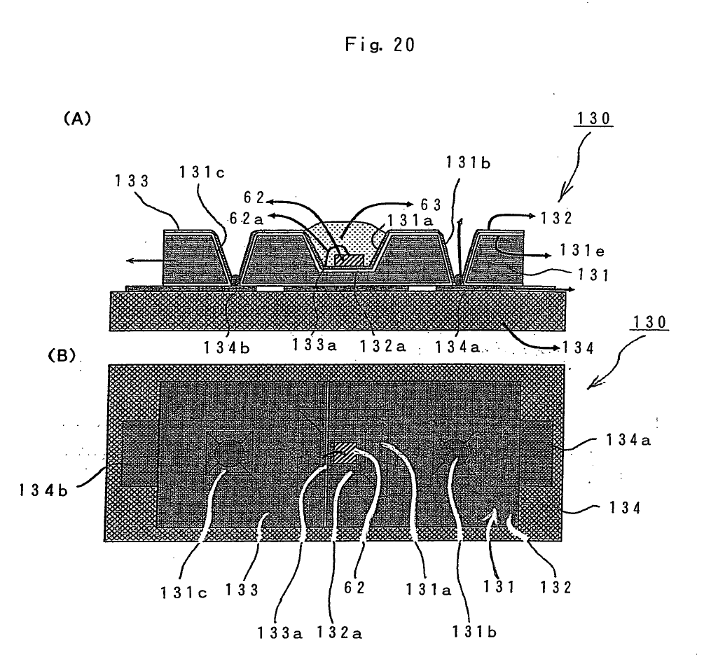

FIG. 20 shows the configuration of a thirteenth embodiment of an LED made in accordance with the principles of the invention.

As shown in FIG. 20, because an LED 130 has substantially the same configuration as that of the LED 60 shown in FIG. 7, the same reference numerals will be given to the same constituent elements and description of those same constituent elements will be omitted.

Namely, the LED 130 is configured by a silicon substrate 131, a LED chip 132 mounted inside a horn 131a formed as a concave recessed portion in the silicon substrate 131, and the resin mold 133 including a resin material filling the inside of the horn 131a.

Here, the silicon substrate 131 is flatly formed so that the surface thereof forms a (100) surface, and is disposed with the two horn 131a formed by the concave recessed portion from the surface to an intermediate height, and furthermore has two contact-hole 131b, 131c formed adjacent this horn 131a, namely adjacent the both side of the horn 131a in a cross-sectional view of FIG. 20(A).

Similar to the horn 131a, these contact-holes 131b, 131c are formed, for example, by liquid phase crystal anisotropic etching with TMAH so that the side surfaces thereof form (111) surfaces.

Additionally, the silicon substrate 131 is disposed with a pair of electrodes 132 and 133 that extend in FIG. 20(A) from the bottom surface of the horn 131a to the surface of the silicon substrate 131 via the left and right side surfaces of the horn 131a and to the ends via respectively left and right contact-holes 131b, 131c.

These electrodes 132 and 133 are formed by, for example, forming a thin metal film on the surface of the silicon substrate 131 in which the horn 131a and contact-holes 131b, 131c have been formed, and then pattern-etching the thin metal film.

Similar to the horn 61a of the LED 60, these horns 131a, 131b are formed, for example, by liquid phase crystal anisotropic etching with TMAH so that the side surfaces thereof form (111) surfaces.

Here, the electrode 132 is disposed with a chip mount portion 132a disposed in a center region of the bottom surface of the horn 131a, and another electrode 133 is disposed with a connection portion 133a that is adjacent to the chip mount portion 132a at the bottom surface of the horn 131a.

Moreover, in this case, both electrodes 132 and 133 are formed so that the surfaces thereof are mirror surfaces at least at regions of the side surfaces of the horn 131a. It should be noted that both electrodes 132 and 133 may also be disposed with separate mirror surfaces at the surfaces thereof at least at the regions of the side surfaces.

The contact-holes 131b, 131c respectively extend to the lower surface of the silicon substrate 131, and the portion of the electrode 132, 133 formed in the contact-holes 131b and 131c are exposed under the lower ends of the contact-holes 131b, 131c.

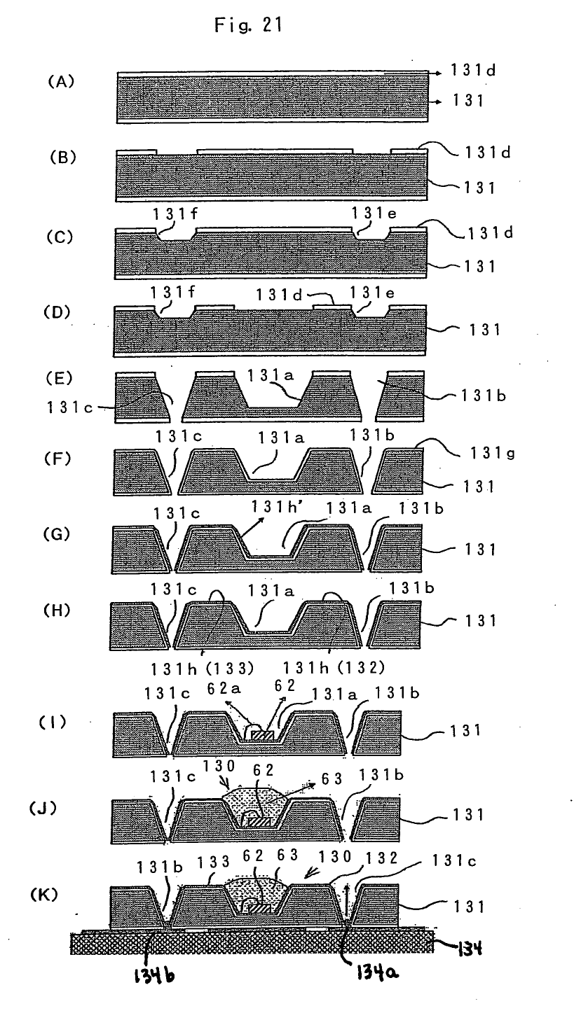

The LED 130 of this configuration is fabricated as follows on the basis of a fabrication method in accordance with the principles of the invention as shown in FIG. 21.

Namely, a silicon substrate 131 of a single crystal silicon wafer with 525 μm thickness is prepared, a (100) surface of which has been flattened by optical polishing process, and on the surface of the silicon substrate 131 is formed a thermal oxidation silicon film 131d with 500 nm thickness by diffusion furnace, as shown in FIG. 21(A).

And, as shown in FIG. 21(B), on the flat surface of the silicon substrate 131 is formed a resist pattern by photolithography method, then the thermal oxidation silicon film 131d is removed selectively by etching of BHF solution so that a pattern of the thermal oxidation silicon film 131d (for forming the contact-holes) is formed.

Thereafter, as shown in FIG. 21(C), the shallow recessed portion 131e, 131f surrounded by an inclined surfaces of (111) surface are formed by liquid phase crystal anisotropic etching with TMAH solution heated at 85° C., then the silicon substrate 131 is drawn up from TMAH solution, and, as shown in FIG. 21(D), again using a resist pattern formed by photolithography method, a pattern of the thermal oxidation silicon film 131d (for forming the horn) is formed.

Next, as shown in FIG. 21(E), the horn 131a and the contact-holes 131b, 131c are formed again by anisotropic etching with TMAH, then the silicon substrate 131 is drawn up from TMHA solution.

And, as shown in FIG. 21(F), the remaining thermal oxidation silicon film 131d can be removed by BHF solution, then on the entire surface of the silicon substrate 131 is formed again a thermal oxidation silicon film 131g with 500 nm thickness by diffusion furnace so that the entire surface of the silicon substrate 131 is insulated.

Next, as shown in FIG. 21(G), an electrode film and a reflecting film 131h′ can be sequentially formed, for example, of Ti and Cu by sputtering method.

Then, by a electroformed resist or a sprayed resist coating, on the entire surface of the silicon substrate 131 is applied a resist, then a patterning of the resist is carried out by photolithography method, and thereafter, by using this resist pattern as a mask, the electrode film and the reflecting film are wet-etched, then, as shown in FIG. 21(H), the electrode pattern 131h (the electrode 132 and 133) are formed. Thereafter, on these electrode pattern, films of Ni with 2 μm thickness and Ag with 3 μm thickness can be formed by, for example, electroplating, thereby the electrode/reflecting film can be formed.

Next, as shown in FIG. 21(I), to the electrode pattern 131h constructing one electrode formed at the bottom portion of the horn 131a, the LED chip 62 is mounted, and die-bonded by reflow-soldering method, eutectic bonding or silver-paste, and the electrode portion of the surface of the LED chip 62 is wire-bonded to the electrode pattern 131h constructing another electrode by the bonding wire 62a.

Then, the inside of the horn 131a is filled with the resin material in which the granular phosphors 63a are mixed in, and the resin material is hardened. Thus, as shown in FIG. 21(J), the resin mold 63 is formed inside the horn 131a. Thus, the LED 130 is completed.

And, in the case of mounting the LED 130 on the mounting board 134, as shown in FIG. 21(K), the package of the LED 130 is put on the determined place of the mounting board 134, the electrodes 132, 133 extending to the lower ends of the contact-holes 131b and 131c is connected to the connecting portion 134a, 134b consist of conductive patterns on the mounting board 134 by reflow-soldering. Thus, the LED 130 is mounted.

According to the LED 130 constructed in this manner, the LED 130 acts in the same manner as the LED 60 shown in FIG. 7, and, when mounting on the mounting boars 134, the electrodes 132, 133 extending to the lower ends of the contact-holes 131b and 131c is directly contacted, and connected by soldering, to the connecting portions 134a, 134b on the mounting board 134, thereby bonding-wire and lead wire are unnecessary, and other parts can be mounted adjacent the LED 130 on the mounting boars 134.

For this LED 130, by a evaluation of light emitting as same as that in the LED 110 with bias of 3V, 350 mA, a white light with 110 mW power was obtained.

### Fourteenth Embodiment

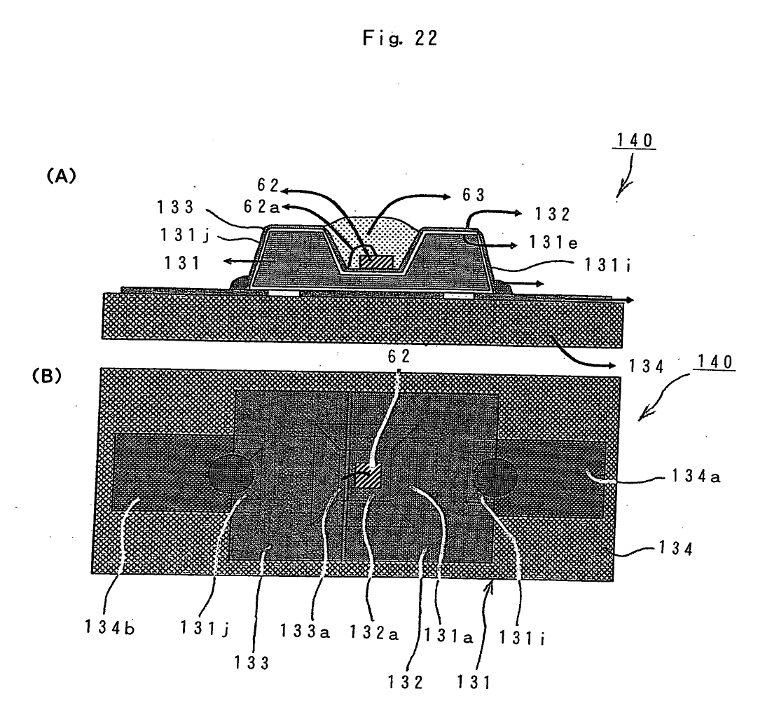

FIG. 22 shows the configuration of a fourteenth embodiment of an LED made in accordance with the principles of the invention.

As shown in FIG. 22, because an LED 140 has substantially the same configuration as that of the LED 130 shown in FIG. 20, the same reference numerals will be given to the same constituent elements and description of those same constituent elements will be omitted.

Namely, the LED 140 is different from the 130 only at the point that the LED 140 is provided with contact-edges 131i, 131j instead of the contact-holes 131b, 131c.

Here, each of the contact-edges 131i, 131j has a form of cutting in half the above mentioned contact-hole 131b or 131c in along centerline at the both end of the silicon substrate 131.

Similar to the horn 131a, these contact-edges 131i, 131j are formed, for example, by liquid phase crystal anisotropic etching with TMAH so that the side surfaces thereof form (111) surfaces.

And, a pair of electrodes 132 and 133 formed on the surface of the silicon substrate 131 extend in FIG. 22(A) from the bottom surface of the horn 131a to the surface of the silicon substrate 131 via the left and right side surfaces of the horn 131a and respectively to the lower ends of the left and right contact-edges 131i, 131j.

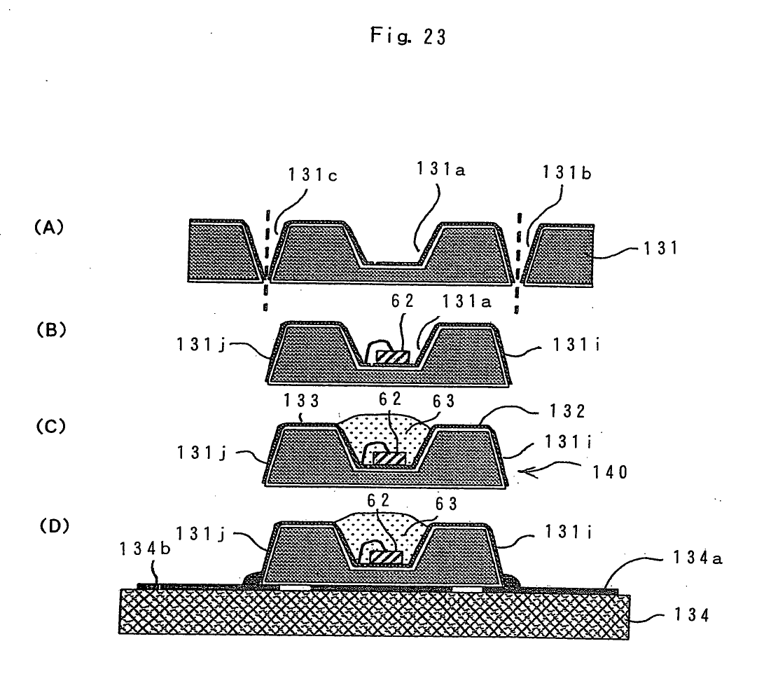

The LED 140 of this configuration is fabricated as follows on the basis of a fabrication method in accordance with the principles of the invention as shown in FIG. 23.

Namely, similar to the LED 120 shown in FIG. 20, as shown in FIGS. 21(A) to (H), on the upper surface of the silicon substrate 131, the horn 131a, the contact-hole 131b and 131c and the electrode pattern 131h.

Here, the electrode pattern 131h (the electrodes 132, 133) extends from the horn 131a to the lower end of the contact-holes 131b, 131c in those via the surface of the silicon substrate 131.

Then, as shown in FIG. 23(A), the silicon substrate 131 is cut off by dicing along a section through the center of each contact-hole 131b, 131c. Thereby, each contact-hole 131b, 131c are cut in half respectively to be the contact-edge 131i, 131j.

Thereafter, as shown in FIG. 23(B), to the electrode pattern 131h constructing one electrode 132 formed at the bottom portion of the horn 131a, the LED chip 62 is mounted, and die-bonded by reflow-soldering method, eutectic bonding or silver-paste, and the electrode portion of the surface of the LED chip 62 is wire-bonded to the electrode pattern 131h constructing another electrode 133 by the bonding wire 62a.

Then, the inside of the horn 131a is filled with the resin material in which the granular phosphors 63a are mixed in, and the resin material is hardened. Thus, as shown in FIG. 23(C), the resin mold 63 is formed inside the horn 131a. Thus, the LED 140 is completed.

And, in the case of mounting the LED 130 on the mounting board 134, as shown in FIG. 23(D), the package of the LED 140 is put on the determined place of the mounting board 134, the electrodes 132, 133 extending to the lower ends of the contact-edges 131i and 131j is connected to the connecting portion 134a, 134b consist of conductive patterns on the mounting board 134 by reflow-soldering. Thus, the LED 140 is mounted.

In this case, because the contact-edges 131i and 131j are provided instead of the contact-holes 131b and 131c, when mounting, a potting of cream solder to the contact-edges 131i, 131j is easily carried out, so that an operativity is improved.

### Fifteenth Embodiment

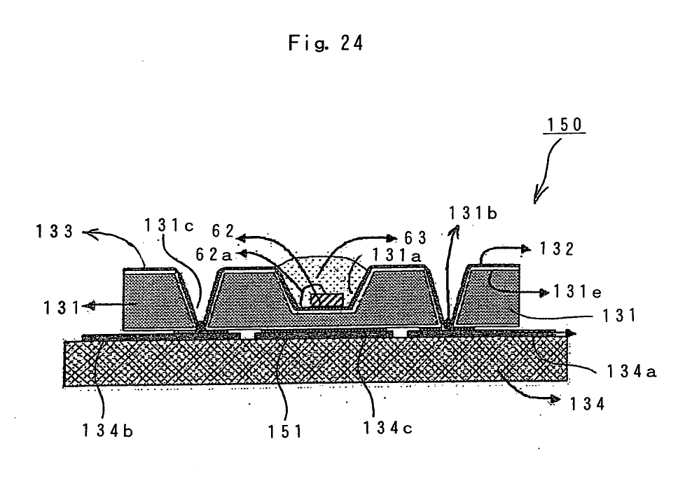

FIG. 24 shows the configuration of a fifteenth embodiment of an LED made in accordance with the principles of the invention.

As shown in FIG. 24, because an LED 150 has substantially the same configuration as that of the LED 130 shown in FIG. 20, the same reference numerals will be given to the same constituent elements and description of those same constituent elements will be omitted.

Namely, the LED 150 is different from the 130 only at the point that a metal thin film 151 is provided in the region corresponding the horn 131a on the backside surface of the silicon substrate 131.

Here, the metal thin film 151 is consist of metal such as Au or Ag, and formed by sputtering, and patterned by lift-off method or wet-etching.

And, in the case of mounting the LED 150 on the mounting board 134, as shown in FIG. 24, the package of the LED 150 is put on the determined place of the mounting board 134, the electrodes 132, 133 extending to the lower ends of the contact-holes 131b and 131c is connected to the connecting portion 134a, 134b consist of conductive patterns on the mounting board 134 by reflow-soldering. Thus, the LED 150 is mounted.

In this case, because the metal thin film 151 provided on the backside surface of the silicon substrate 131 contacts to the conductive pattern portion 134c for heat-radiation on the mounting board 134, the heat generated from the LED chip 62 is transmitted from the silicon substrate 131 to the conductive pattern portion 134c for heat-radiation via the metal thin film 151, thereby the heat generated from the LED chip 62 can be radiated efficiently.

### Sixteenth Embodiment

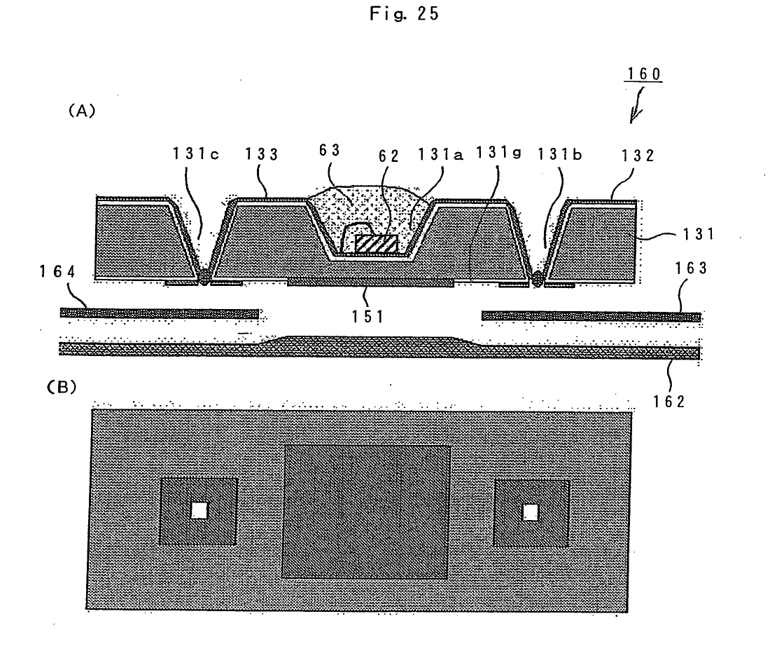

FIG. 25 shows the configuration of a sixteenth embodiment of an LED made in accordance with the principles of the invention.

As shown in FIG. 25, an LED 160 is a variant of the LED 150 shown in FIG. 24.

Namely, the LED 160 is different from the 150 only at the point that the thermal oxidation silicon film 131g is removed in a region, that the metal thin film 151 is formed in, on the lower surface of the silicon substrate 131.

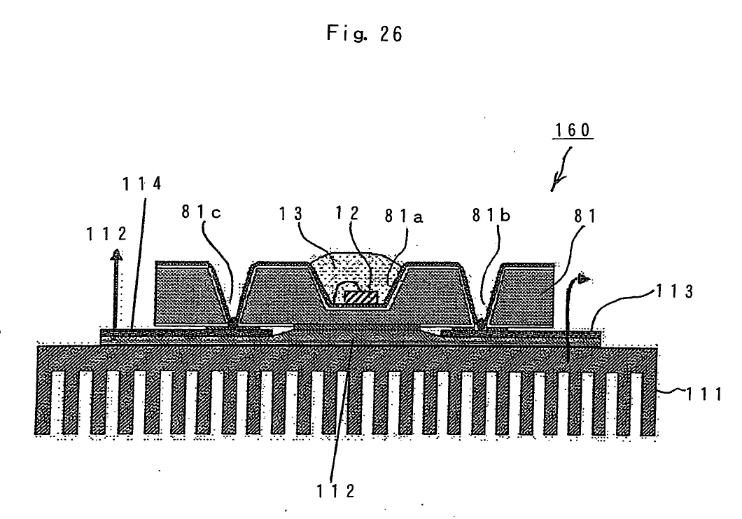

According to the LED 160 of this configuration, in the case of mounting the LED 160 on the heat sink 161, as shown in FIG. 26, the package of the LED 160 is put on the surface of the heat sink 161 by inserting a thermal conductive sheet 162, and the contact-holes 131b, 131c is put on the lead frame 163, 164, then the electrodes 132, 133 extending to the lower ends of the contact-holes 131b and 131c is connected respectively to the lead frames 163, 164 by reflow-soldering. Thus, the LED 160 is mounted.

In this case, because the metal thin film 151 provided on the lower surface of the silicon substrate 131 contacts directly to the lower surface of the silicon substrate 131 and via the thermal conductive sheet 162 to the heat sink 161, the heat from the LED chip 62 is transmitted from the silicon substrate 131 to the heat sink 161 via the thermal conductive sheet 162, thereby the heat resistance is reduced extremely, for example, as 2° C./W, so that an effect of heat radiation is raised.

### Seventeenth Embodiment

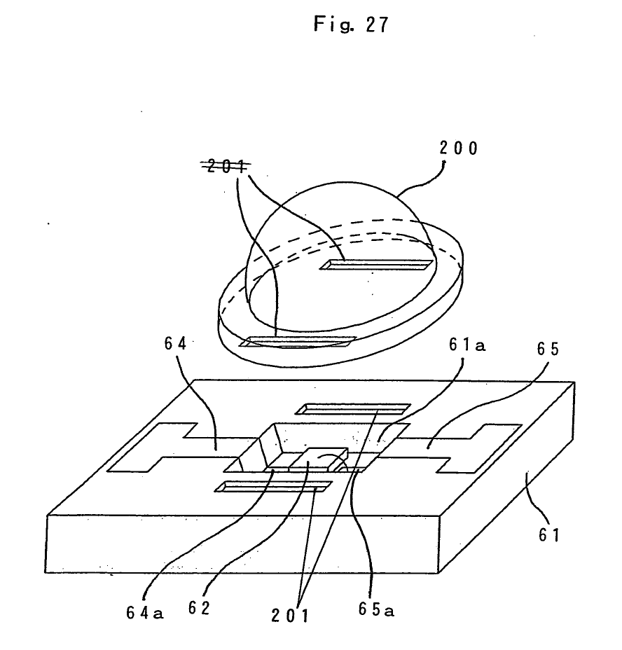

FIG. 27 shows the configuration of a seventeenth embodiment of an LED made in accordance with the principles of the invention.

As shown in FIG. 27, because an LED has substantially the same configuration as that of the LED 60 shown in FIG. 7, the same reference numerals will be given to the same constituent elements and description of those same constituent elements will be omitted.

Namely, the LED is configured by a silicon substrate 61, a horn 61a formed as a concave recessed portion in the silicon substrate 61, a LED chip 62 mounted center of the horn 61a, the resin mold 63 including a resin material filling the inside of the horn 61a, and a lens 200.

This lens 200 is arranged above the horn 61a before the resin mold 63 filled in the horn 61a is hardened, then fixed by hardening of the resin mold 63. Particularly a recess 201 for positioning the lens 200 is adjacent the horn 61a, thereby the lens can be mounted precisely and easily. This recess 201 can be formed at the same time by liquid phase etching for forming the horn, thereby the accuracy of mask for etching can be brought to the positioning accuracy of the lens 200 substantially.

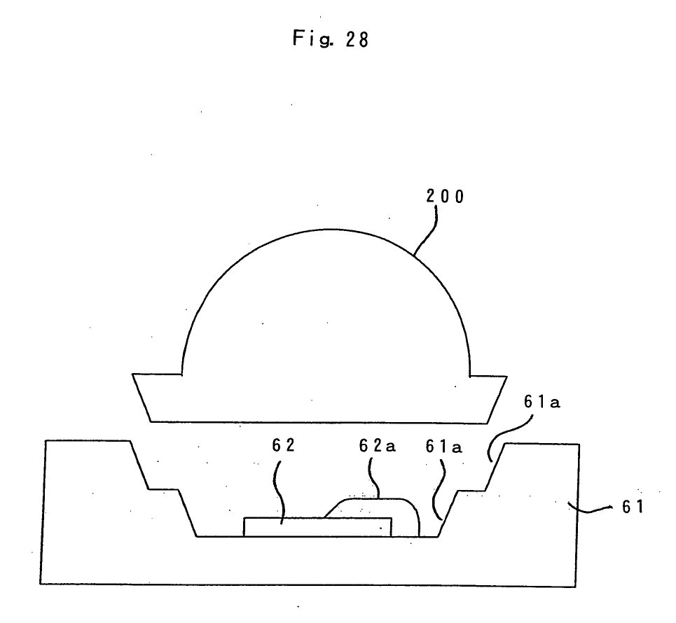

Additionally, in FIG. 27, two rectangular recesses 201 are formed; however three or more recesses 201 can be formed, or substantially circular or polygonal recesses surrounding the horn can be formed. Also, as shown in FIG. 28, the horn is formed with two steps, thereby the upper step can be used as a recess for positioning the lens 200.

### Eighteenth Embodiment

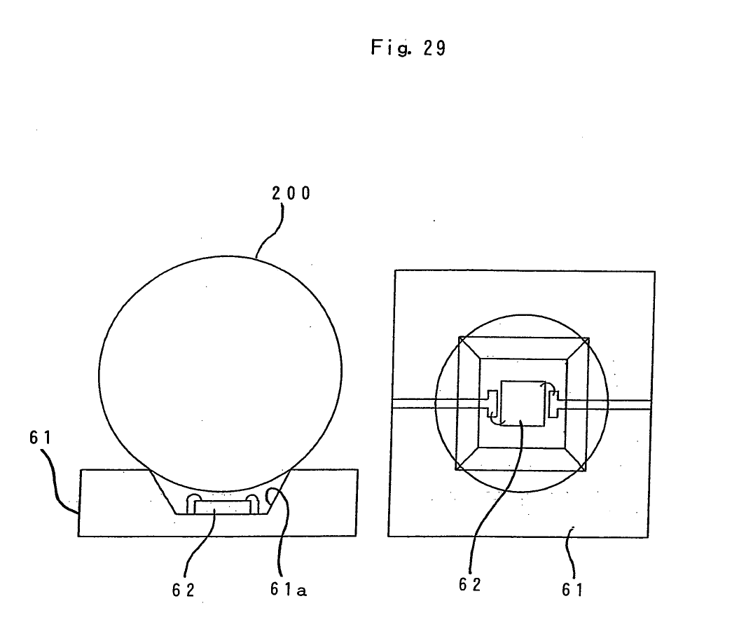

FIG. 29 shows the configuration of an eighteenth embodiment of an LED made in accordance with the principles of the invention.

As shown in FIG. 29, because an LED has substantially the same configuration as that of the LED 60 shown in FIG. 7, the same reference numerals will be given to the same constituent elements and description of those same constituent elements will be omitted.

Namely, the LED is configured by a silicon substrate 61, a horn 61a formed as a concave recessed portion in the silicon substrate 61, a LED chip 62 mounted center of the horn 61a, the resin mold 63 including a resin material filling the inside of the horn 61a, and a spherical lens 200.

This spherical lens 200 is arranged above the horn 61a before the resin mold 63 filled in the horn 61a is hardened, then fixed by hardening of the resin mold 63. Particularly, in the case of the horn formed in a square shape, by fixing the spherical lens 200 against the edge of the horn 61a, the spherical lens 200 can be positioned uniquely, thereby advantageously an offset of the optical axis is hard to occur material of the lens itself can be light-transparent material such as glass, resin material, and can have a good adhesion to the mold resin since the lens is adhered and fixed to the mold resin.

### Nineteenth Embodiment

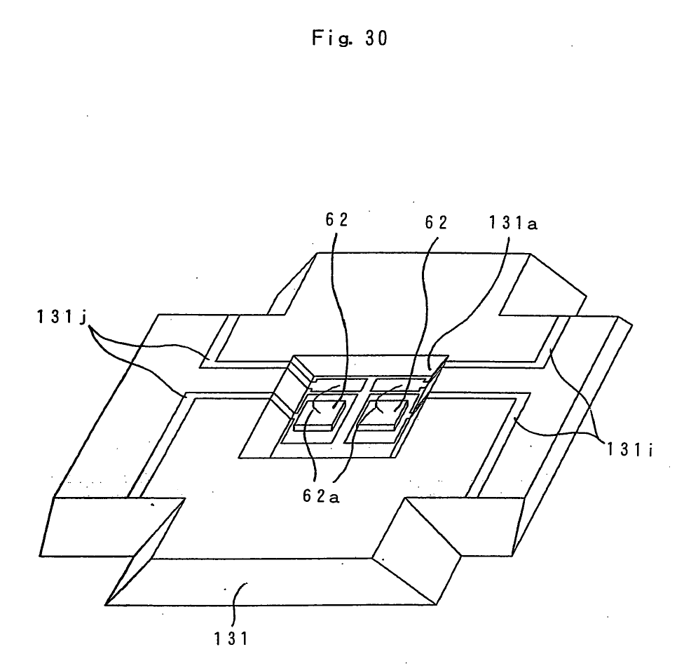

FIG. 30 shows the configuration of a nineteenth embodiment of an LED made in accordance with the principles of the invention.

As shown in FIG. 30, because an LED has substantially the same configuration as that of the LED 140 shown in FIG. 22, the same reference numerals will be given to the same constituent elements and description of those same constituent elements will be omitted.

Namely, the LED is configured by a silicon substrate 131, a horn 131a formed as a concave recessed portion in the silicon substrate 131, a plural of LED chips 62 mounted center of the horn 131a, the resin mold 63 including a resin material filling the inside of the horn 131a, and contact-edges 131i, 131j.

Here, the contact-edges are formed respectively at four corners of the rectangular bottom surface of the horn 131a, and the electricity can be supplied via each contact-edge to corresponding LED chip. Thereby, when, for example, a red LED chip and a green LED chip are mounted in the same horn, light emitting of each LED chip can be controlled individually through an external circuit. Additionally, in FIG. 30, by using four electrodes, two LED chips are electrically connected and driven individually; however by forming other contact-edge in a vicinity of the silicon substrate 131, each of tree or more LED chips can be electrically connected independently.

### Twentieth Embodiment

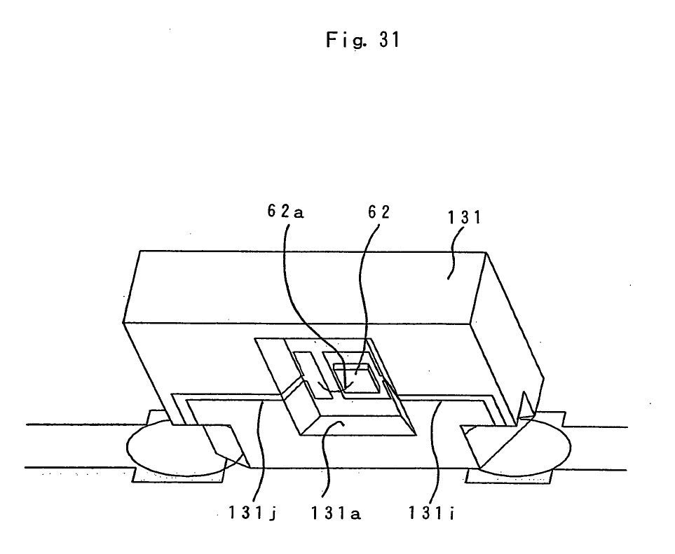

FIG. 31 shows the configuration of a twentieth embodiment of an LED made in accordance with the principles of the invention.

As shown in FIG. 31, because an LED has substantially the same configuration as that of the LED 140 shown in FIG. 22, the same reference numerals will be given to the same constituent elements and description of those same constituent elements will be omitted.

Namely, the LED is configured by a silicon substrate 131, a horn 131a formed as a concave recessed portion in the silicon substrate 131, a plural of LED chips 62 mounted center of the horn 131a, the resin mold 63 including a resin material filling the inside of the horn 131a, and contact-edges 131i, 131j.

Here, the contact-edges are formed respectively at two positioned adjacent each other of four corners of the bottom surface of the horn 131a, and, the LED will be mounted on the mounting board so that the horn, in which the LED chips are mounted, opens to the direction parallel to the substrate. Namely, the LED of this embodiment is configured as a side-view type surface-mounting type LED.

### Twenty-first Embodiment

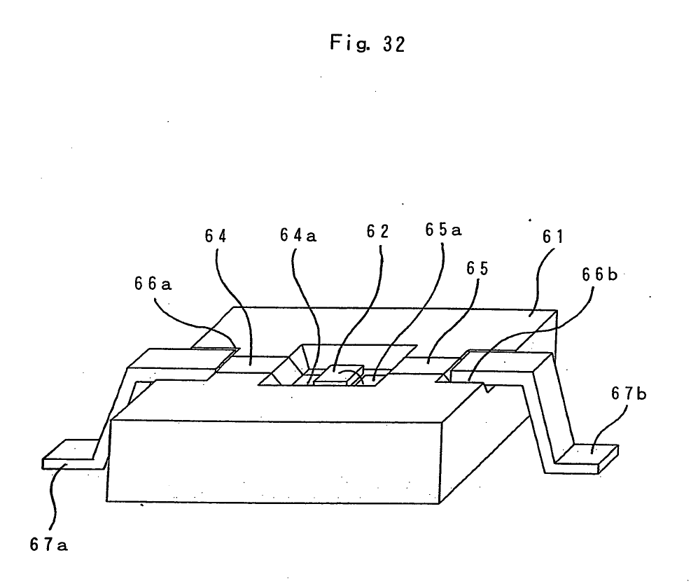

FIG. 32 shows the configuration of a twenty-first embodiment of an LED made in accordance with the principles of the invention.

As shown in FIG. 32, because an LED has substantially the same configuration as that of the LED 60 shown in FIG. 7, the same reference numerals will be given to the same constituent elements and description of those same constituent elements will be omitted.

Namely, the LED is configured by a silicon substrate 61, a horn 61a formed as a concave recessed portion in the silicon substrate 61, a plural of LED chips 62 mounted center of the horn 61a, the resin mold 63 including a resin material filling the inside of the horn 61a, and lead frames 67a, 67b.

Here, the LED is different from the LED 60 in FIG. 7 at the point that the lead frames 67a, 67b are mounted at the left and right side of the silicon substrate 61 respectively so as to be electrically connected to the electrodes. Thereby, a thin surface-mounting type device can be produced to be suited for mounting.

In fabricating the LED, shallow recesses 66a, 66b for positioning the lead frames can be formed in the silicon substrate 61. Since these recesses 66a, 66b can be formed at the same time that the horn is formed by liquid phase etching, additional process is not necessary.

For the lead frames are certainly connected to the electrode contact portions on the silicon substrate, electric connection are carried out using a conductive paste. Electric connection can be carried out using eutectic bonding or laser beam welding. In this case, mechanical rigidity in each bonding of the lead frames and the silicon substrate is highly, thereby the LED is easily treated when mounting.

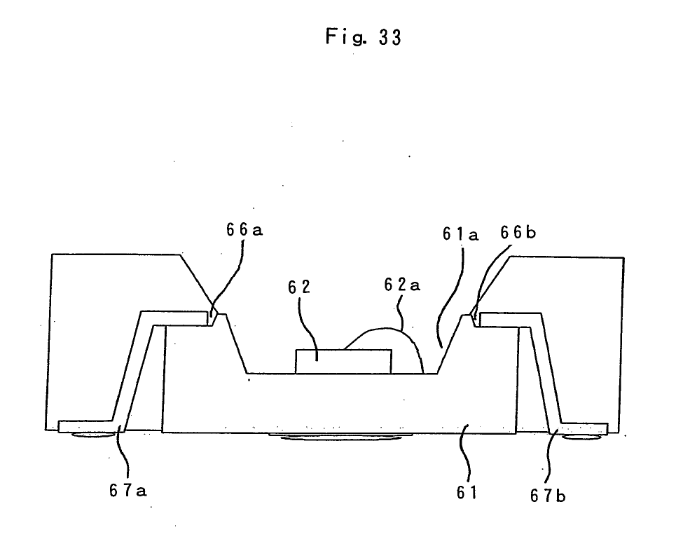

Also, in FIG. 33, a LED is shown that the silicon substrate with the lead frames is molded integratedly with the resin mold. In the case, the resin penetrates between the lead frames and the silicon substrate, thereby a short-circuit can be prevented, so that a reliability is raised. Also, the lead frames are fixed by the resin, thereby the mechanical rigidity is increased more, so that the LED can be treated.

Furthermore, a metal thin film can be formed in a region corresponding to the LED chips in the lower surface of the silicon substrate, so that the lead frames and the metal thin film will be fixed to a mounting board by reflow-soldering process. Thereby, the region of the backside of silicon substrate that corresponds to the bottom surface of the LED chip is directly contacted to the mounting board via solder, so that the heat-radiation is improved.

In the preceding embodiments, the LED was configured so that the phosphors mixed inside the resin mold were excited by the blue light from the LED chip and so that white light was emitted due to the mixing of the colors of the excitation light and the blue light from the LED chip; however, it will be apparent that the LED may also be one where the light from the LED chip is emitted as is to the outside by a resin mold in which the phosphors are not mixed in.

Also, in the preceding embodiments, only the LED chip was mounted on the silicon substrate, but the invention is not limited thereto. It will be apparent that other semiconductor devices may also be integrally configured on the silicon substrate by a semiconductor fabrication process.

Moreover, in the preceding embodiments, the mirror surface was disposed on the side walls of the horn on the silicon substrate, but the invention is not limited thereto. It will be apparent that the mirror surface does not have to be disposed.

According to an embodiment of an LED made in accordance with the principles of the invention, an LED chip can be mounted inside a horn formed on a silicon substrate, whereby the LED can be compactly configured at a relatively low cost. Also, because the LED can easily accommodate multichip LED fabrication, it is possible to use the LED as a light source for various devices.

While illustrative and exemplary embodiments of the invention have been described in detail herein, it is to be understood that the inventive concepts may be otherwise variously embodied and employed and that the appended claims are intended to be construed to include such variations except insofar as limited by the prior art.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. An LED comprising:
a silicon substrate including a horn formed by anisotropic etching;
a pair of electrodes located inside the horn;
an LED chip located inside the horn, the LED chip being electrically connected to the pair of electrodes; and
a resin mold made of a resin material that is filled in the horn.

39. The LED according to claim 38, wherein
the horn is formed by etching the silicon substrate from an upper surface of the silicon substrate to an intermediate height, and wherein
each electrode is formed so as to extend along the surface of the silicon substrate from a bottom surface of the horn via side surfaces of the horn.

40. The LED according to claim 38, wherein the silicon substrate includes a flat first substrate having a surface on which the electrodes are formed and a second substrate laminated on the first substrate, the second substrate being provided with the horn, and the horn vertically penetrates the second substrate.

41. The LED according to claim 38, wherein the LED chip is die-bonded to one of the pair of electrodes inside the horn and is wire-bonded to the other of the pair of electrodes inside the horn.

42. The LED according to claim 38, wherein the LED chip is mounted so as to straddle the pair of electrodes inside the horn, with electrodes formed at both lower side edges of the LED chip being electrically connected respectively to the pair of electrodes inside the horn.

43. The LED according to claim 38, wherein the silicon substrate is formed with a (100) surface serving as an outer surface, and wherein the side surfaces of the horn are formed as (111) surfaces.

44. The LED according to claim 38, wherein the horn includes a side surface that includes a mirror surface.

45. The LED according to claim 38, wherein an actuator and an IC circuit are located adjacent to the horn on the silicon substrate.

46. The LED according to claim 38, wherein granular phosphors are mixed in with the resin material forming the resin mold.

47. A method of fabricating an LED comprising:
providing a silicon substrate, the silicon substrate having a surface;
forming a horn in the surface of the silicon substrate by anisotropic etching;
locating a pair of electrodes in the horn;
mounting an LED chip inside the horn such that the LED chip is electrically connected to the pair of electrodes; and
filling the interior of the horn with a resin material to form a resin mold.

48. An LED comprising:
a silicon substrate;
a horn formed on the silicon substrate by liquid phase etching;
at least two electrodes located inside the horn; and
at least one LED chip located inside the horn, the LED chip being electrically connected to the electrodes.

49. The LED according to claim 48, wherein
the electrodes are drawn out from the horn, and are electrically connected with lead frames.

50. The LED according to claim 48, wherein
the horn is formed by etching the silicon substrate from an upper surface of the silicon substrate to a height above a lower surface so as not to pass completely through the substrate, and wherein
each electrode extends along the surface of the silicon substrate from a bottom surface of the horn via a side surface of the horn.

51. The LED according to claim 48, wherein
the silicon substrate includes a flat first substrate having a surface on which the electrodes are formed and a second substrate laminated on the first substrate, the second substrate being provided with the horn, and the horn vertically penetrates the second substrate.

52. The LED according to claim 48, wherein
each LED chip is die-bonded to one of the electrodes inside the horn and is wire-bonded to another of the electrodes inside the horn.

53. The LED according to claim 48, wherein
the at least one LED chip is mounted so as to straddle two of the electrodes inside the horn, and including chip electrodes formed at both lower side edges of the LED chip being electrically connected respectively to the two electrodes inside the horn.

54. The LED according to claim 48, wherein
the horn includes side surfaces formed as at least one of (111), (110) and (100) surfaces.

55. The LED according to claim 48, wherein
the horn includes side surfaces provided with a mirror surface.

56. The LED according to claim 48, wherein
an actuator is located on the silicon substrate.

57. The LED according to claim 48, wherein
an electronic circuit is located on the silicon substrate.

58. The LED according to claim 48, wherein
the electronic circuit is at least one of a photo-diode, a transistor and an IC.

59. The LED according to claim 48, wherein
a resin is filled in the horn.

60. The LED according to claim 59, wherein
phosphors are mixed in with the resin.

61. The LED according to claim 48, wherein
the horn has a partition wall that surrounds each LED chip respectively.

62. The LED according to claim 61, wherein
an upper end of the partition wall is flat and substantially co-planar with an upper surface of the silicon substrate.

63. The LED according to claim 61, wherein
an upper end of the partition has a crest line that is substantially co-planar with an upper surface of the silicon substrate.

63. The LED according to claim 61, wherein
an upper end of the partition has a crest line located lower than an upper surface of the silicon substrate.

64. The LED according to claim 61, wherein
the side surface of the partition wall has one of a flat, convex and concave form.

65. The LED according to claim 61, wherein
a side surface of the partition is formed as at least one of a (111), a (110) and a (100) surface.

66. An LED comprising:
a silicon substrate;
a horn formed on the silicon-substrate by liquid phase etching;
at least two contact-holes formed on the silicon substrate by liquid phase etching;
at least two electrodes extending from an inside of the horn to a lower end of the contact-holes; and
at least one LED chip located inside the horn, the LED chip being electrically connected to the electrodes.

67. An LED comprising:
a silicon substrate;
a horn formed on the silicon substrate by liquid phase etching;
at least two contact-edges formed on the silicon substrate by liquid phase etching;
at least two electrodes extending from an inside of the horn to a lower end of the contact-edges; and
at least one LED chip located inside the horn, the LED chip being electrically connected to the electrodes.

68. The LED according to claim 67, wherein
the silicon substrate has an LED-mounted side on which the LED is located, and has a rectangular form as viewed from the LED-mounted side, and at least one of the contact-edges is formed at least on one of four corners of the rectangular form.

69. The LED according to claim 66, wherein
a metal thin film is provided on a lower surface of the silicon substrate at least in a region of the horn.

70. The LED according to claim 69, wherein
the silicon substrate connectable to a heat-radiating member via the metal thin film.

71. The LED according to claim 67, wherein
a lens is located on the horn.

72. The LED according to claim 71, wherein
the lens is a convex lens.

73. The LED according to claim 71, wherein
the lens is a spherical lens.

74. The LED according to claim 71, wherein
a recess for positioning the lens is formed adjacent the horn on the silicon substrate.

75. A method of fabricating an LED comprising:
forming a horn on a silicon substrate by liquid phase etching;
forming at least two electrodes inside the horn;
mounting at least one LED chip inside the horn such that the LED chip is electrically connected to the electrodes.

76. The method according to claim 75, further comprising:
filling the interior of the horn with a resin material to form a resin mold.

77. The method according to claim 75, wherein
forming a horn on the silicon substrate by liquid phase etching includes forming a plurality of horns adjacent each other, and forming a partition wall between the horns.

78. The method according to claim 77, wherein
forming the partition wall includes forming an upper end of the partition wall such that it is substantially co-planar with, or lower than, an upper surface of the silicon substrate.

79. The method according to claim 77, wherein
a surface of the partition wall has one of a convex and a concave form.

80. A method of fabricating an LED comprising:
providing a silicon substrate;
forming an oxidized film on a surface of the silicon substrate;
patterning the oxidized film so as to expose each portion of the silicon substrate that is to form a contact-hole;
forming a shallow recess in each portion that is to form a contact-hole by liquid phase etching;
patterning the oxidized film so as to expose each portion of the silicon substrate that is to form a horn;
forming horns and contact-holes on the silicon substrate by liquid phase etching;
providing an insulating film on the surface of the silicon substrate;
forming electrode-patterns on the silicon substrate;
mounting at least one LED chip inside each horn such that the LED chip is electrically connected to the electrodes; and
cutting out at least a portion of the silicon substrate.

81. A method of fabricating an LED comprising:
providing a silicon substrate;
forming an oxidized film on a surface of the silicon substrate;
patterning the oxidized film so as to expose each portion of the silicon substrate that is to form a through-bore;
forming a shallow recess in each portion that is to form a through-bore by liquid phase etching;
patterning the oxidized film so as to expose each portion of the silicon substrate that is to form a horn;
forming horns and through-bores on the silicon substrate by liquid phase etching;
providing an insulating film on the surface of the silicon substrate;
providing electrode-patterns on the silicon substrate;
mounting at least one LED chip inside each horn such that the LED chip is electrically connected to the electrodes; and
cutting out at least a portion of the silicon substrate so as to cross each through-bore and form a contact edge.

82. A method of fabricating an LED comprising:
forming at least two electrodes on a first silicon substrate;
forming through-bores on a second silicon substrate by liquid phase etching and forming a horn on a side wall of each through-bore;
bonding the first and second silicon substrates to each other so as to expose the electrodes in each through-bore; and
mounting at least one LED chip inside the horn such that the LED chip is electrically connected to the electrodes.

83. The method according to claim 82, further including:
at least one of
forming a mirror surface in an inner surface of each through-bore,
filling the interior of the horn with a resin material to form a resin mold, and
insulating the surfaces of silicon substrates by oxidized film.

84. The LED according to claim 67, wherein
a metal thin film is provided on the lower surface of the silicon substrate at least in the region of the horn.
